(19) United States
(12) Patent Application Publication
(10) Pub. No.: US 2022/0052262 A1
(43) Pub. Date: Feb. 17, 2022

(54) METHOD OF MANUFACTURING PEROVSKITE LIGHT EMITTING DEVICE BY INKJET PRINTING

(71) Applicant: PEROLED LIMITED, Sedgefield (GB)

(72) Inventor: Peter LEVERMORE, Sedgefield (GB)

(21) Appl. No.: 17/276,871

(22) PCT Filed: Sep. 16, 2019
(86) PCT No.: PCT/GB2019/052596

§ 371 Date: Mar. 17, 2021

(30) Foreign Application Priority Data
Sep. 17, 2018 (GB) 1815061.5

(51) Int. Cl. H01L 51/00

(52) U.S. Cl. CPC H01L 51/0005; H01L 51/56; H01L 51/0029

(57) ABSTRACT

A method of assembling a perovskite emissive layer is provided. The method comprises the steps of: providing a substrate; providing a bank structure disposed over the substrate, wherein the bank structure is patterned so as to define at least one sub-pixel on the substrate; providing a perovskite ink, wherein the perovskite ink comprises at least one solvent and at least one perovskite light emitting material mixed in the at least one solvent; depositing the perovskite ink into the at least one sub-pixel over the substrate using a method of inkjet printing; and vacuum drying the perovskite ink inside a vacuum drying chamber to assemble a perovskite emissive layer in the at least one sub-pixel. A perovskite emissive layer assembled using the provided method is also provided. A perovskite light emitting device comprising a perovskite emissive layer assembled using the provided method is also provided.

### TECHNICAL FIELD

The present invention relates to perovskite emissive layers comprising perovskite light emitting material, and in particular to methods of assembling perovskite emissive layers comprising perovskite light emitting material. The present invention also relates to perovskite light emitting devices comprising perovskite emissive layers, and in particular to methods of assembling perovskite light emitting devices comprising perovskite emissive layers.

### BACKGROUND

Perovskite materials are becoming increasingly attractive for application in optoelectronic devices. Many of the perovskite materials used to make such devices are earth-abundant and relatively inexpensive, so perovskite optoelectronic devices have the potential for cost advantages over alternative organic and inorganic devices. Additionally, inherent properties or perovskite materials, such as an optical band gap that is readily tunable across the visible, ultra-violet and infra-red, render them well suited for optoelectronics applications, such as perovskite light emitting diodes (PeLEDs), perovskite solar cells and photodetectors, perovskite lasers, perovskite transistors, perovskite visible light communication (VLC) devices and others. PeLEDs comprising perovskite light emitting material may have performance advantages over conventional organic light emitting diodes (OLEDs) comprising organic light emitting material. For example, strong electroluminescent properties, including unrivalled high colour purity, enabling displays with wider colour gamut, excellent charge transport properties and low non-radiative rates.

PeLEDs make use of thin perovskite films that emit light when voltage is applied. PeLEDs are becoming an increasingly attractive technology for use in applications such as displays, lighting and signage. As an overview, several PeLED materials and configurations are described in Adjokatse et al., which is included herein by reference in its entirety.

One potential application for perovskite light-emitting materials is a display. Industry standards for a full-colour display require for sub-pixels to be engineered to emit specific colours, referred to as “saturated” colours. These standards call for saturated red, green and blue sub-pixels, where colour may be measured using CIE 1931 (x, y) chromaticity coordinates, which are well known in the art. One example of a perovskite material that emits red light is methylammonium lead iodide (CH₃NH₃PbI₃). One example of a perovskite material that emits green light is formamidinium lead bromide (CH(NH₂)₂PbBr₃). One example of a perovskite material that emits blue light is methylammonium lead chloride (CH₃NH₃PbCl₃). In a display, performance advantages, such as increased colour gamut, may be achieved where PeLEDs are used in place of or in combination with OLEDs.

The present invention relates to perovskite emissive layers comprising perovskite light emitting material, and in particular to methods of assembling perovskite emissive layers comprising perovskite light emitting material. The present invention also relates to perovskite light emitting devices comprising perovskite emissive layers, and in particular to methods of assembling perovskite light emitting devices comprising perovskite emissive layers.

As used herein, the term “perovskite” includes any perovskite material that may be used in an optoelectronic device. Any material that may adopt a three-dimensional (3D) structure of ABX₃, where A and B are cations and X is an anion, may be considered a perovskite material. FIG. 1 depicts an example of a perovskite material with a 3D structure of ABX₃. The A cations may be larger than the B cations. The B cations may be in 6-fold coordination with surrounding X anions. The A anions may be in 12-fold coordination with surrounding X anions.

There are many classes of perovskite material. One class of perovskite material that has shown particular promise for optoelectronic devices is the metal halide perovskite material class. For metal halide perovskite material, the A component may be a monovalent organic cation, such as methylammonium (CH₃NH₃⁻) or formamidinium (CH(NH₂)₂⁺), an inorganic atomic cation, such as caesium (Cs⁺), or a combination thereof, the B component may be a divalent metal cation, such as lead (Pb⁺), tin (Sn⁺), copper (Cu⁺), europium (Eu⁺) or a combination thereof, and the X component may be a halide anion, such as I⁻, Br⁻, Cl⁻, or a combination thereof. Where the A component is an organic cation, the perovskite material may be defined as an organic metal halide perovskite material. CH₃NH₃PbBr₃ and CH(NH₂)₂PbI₃ are non-limiting examples of organic metal halide perovskite materials with a 3D structure. Where the A component is an inorganic cation, the perovskite material may be defined as an inorganic metal halide perovskite material. CsPbI₃, CsPbCl₃ and CsPbBr₃ are non-limiting examples of inorganic metal halide perovskite materials.

As used herein, the term “perovskite” further includes any material that may adopt a layered structure of L₂(ABX₃)ₙ₋₁BX₄ (which may also be written as L₂Aₙ₋₁BₙX₃ₙ₊₁), where L, A and B are cations, X is an anion, and n is the number of BX₄ monolayers disposed between two layers of cation L. FIG. 2 depicts examples of perovskite materials with a layered structure of L₂(ABX₃)ₙ₋₁BX₄ having different values for n. For metal halide perovskite material, the A component may be a monovalent organic cation, such as methylammonium (CH₃NH₃⁺) or formamidinium (CH(NH₂)₂⁺), an atomic cation, such as caesium (Cs⁺), or a combination thereof, the L component may be an organic cation such as 2-phenylethylammonium (C₆H₅C₂H₄NH₃⁺) or 1-napthylmethylammonium (C₁₀H₇CH₂NH₃⁺), the B component may be a divalent metal cation, such as lead (Pb⁺), tin (Sn⁺), copper (Cu⁺), europium (Eu⁺) or a combination thereof, and the X component may be a halide anion, such as I⁻, Br⁻, Cl⁻, or a combination thereof. (C₆H₅C₂H₄NH₃)₂(CH(NH₂)₂PbBr₃)ₙ₋₁PbBr₄ and (C₁₀H₇CH₂NH₃)₂(CH₃NH₃PbI₂Br)ₙ₋₁PbI₃Br are non-limiting examples of metal halide perovskite material with a layered structure.

Where the number of layers n is large, for example n greater than approximately 10, perovskite material with a layered structure of L₂(ABX₃)ₙ₋₁BX₄ adopts a structure that is approximately equivalent to perovskite material with a 3D structure of ABX₃. As used herein, and as would generally be understood by one skilled in the art, perovskite material having a large number of layers may be referred to as a 3D perovskite material, even though it is recognized that such perovskite material has reduced dimensionality from n=∞. Where the number of layers n=1, perovskite material with a layered structure of L₂(ABX₃)ₙ₋₁BX₄ adopts a two-dimensional (2D) structure of L₂BX₄. Perovskite material having a single layer may be referred to as a 2D perovskite material. Where n is small, for example n in the range of approximately 2-10, perovskite material with a layered structure of L₂(ABX₃)ₙ₋₁BX₄ adopts a quasi-two-dimensional (Quasi-2D) structure. Perovskite material having a small number of layers may be referred to as a Quasi-2D perovskite material. Owing to quantum confinement effects, the energy band gap is lowest for layered perovskite material structures where n is highest.

Perovskite material may have any number of layers. Perovskites may comprise 2D perovskite material, Quasi-2D perovskite material, 3D perovskite material or a combination thereof. For example, perovskites may comprise an ensemble of layered perovskite materials having different numbers of layers. For example, perovskites may comprise an ensemble of Quasi-2D perovskite materials having different numbers of layers.

As used herein, the term “perovskite” further includes films of perovskite material. Films of perovskite material may be crystalline, polycrystalline or a combination thereof, with any number of layers and any range of grain or crystal size.

As used herein, the term “perovskite” further includes nanocrystals of perovskite material that have structure equivalent to or resembling the 3D perovskite structure of ABX₃ or the more general layered perovskite structure of L₂(ABX₃)ₙ₋₁BX₄. Nanocrystals of perovskite material may include perovskite nanoparticles, perovskite nanowires, perovskite nanoplatelets, or a combination thereof. Nanocrystals of perovskite material may be of any shape or size, with any number of layers and any range of grain or crystal sizes. FIG. 3 depicts an example of nanocrystal of perovskite material with a layered structure that resembles L₂(ABX₃)ₙ₋₁BX₄, where n=5 and L cations are arranged at the surface of the perovskite nanocrystal. The term “resembles” is used because for a nanocrystal of perovskite material, the distribution of L cations may differ from that of perovskite material with a formal layered structure of L₂(ABX₃)ₙ₋₁BX₄. For example, in a nanocrystal of perovskite material, there may be a greater proportion of L cations arranged along the sides of the nanocrystal.

Several types of perovskite material may be stimulated to emit light in response to optical or electrical excitation. That is to say that perovskite light emitting material may be photoluminescent or electroluminescent. As used herein, the term “perovskite light emitting material” refers exclusively to electroluminescent perovskite light emitting material that is emissive through electrical excitation. Wherever “perovskite light emitting material” is referred to in the text, it should be understood that reference is being made to electroluminescent perovskite light emitting material. This nomenclature may differ slightly from that used by other sources.

In general, PeLED devices may be photoluminescent or electroluminescent. As used herein, the term “PeLED” refers exclusively to electroluminescent devices that comprise electroluminescent perovskite light emitting material. When current is applied to such PeLED devices, the anode injects holes and the cathode injects electrons into the emissive layer(s). The injected holes and electrons each migrate towards the oppositely charged electrode. When an electron and a hole localize, an exciton, which is a localized electron-hole pair having an excited energy state, may be formed. Light is emitted if the exciton relaxes via a photo-emissive mechanism. The term “PeLED” may be used to describe single emissive unit electroluminescent devices that comprise electroluminescent perovskite light emitting material. The term “PeLED” may also be used to describe one or more emissive units of stacked electroluminescent devices that comprise electroluminescent perovskite light emitting material. This nomenclature may differ slightly from that used by other sources.

As used herein, “top” means furthest away from the substrate, while “bottom” means closest to the substrate. Where a first layer is described as “disposed over” a second layer, the first layer is disposed further away from the substrate. There may be other layers between the first and second layer, unless it is specified that the first layer is “in contact with” the second layer. Where a first layer is described as “in contact with” a second layer, the first layer is adjacent to the second layer. That is to say the first layer is in direct physical contact with the second layer, with no additional layers, gaps or spaces disposed between the first layer and the second layer.

As used herein, “solution processible” means capable of being dissolved, dispersed or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) and electron affinities (EA) are measured as negative energies relative to a vacuum level, a higher HOMO energy level corresponds to an IP that is less negative. Similarly, a higher LUMO energy level corresponds to an EA that is less negative. On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. The definitions of HOMO and LUMO energy levels therefore follow a different convention than work functions.

### SUMMARY

A method of assembling a perovskite emissive layer is provided. In one embodiment, the method comprises the steps of: providing a substrate; providing a bank structure disposed over the substrate, wherein the bank structure is patterned so as to define at least one sub-pixel on the substrate; providing a perovskite ink, wherein the perovskite ink comprises at least one solvent and at least one perovskite light emitting material mixed in the at least one solvent; depositing the perovskite ink into the at least one sub-pixel over the substrate using a method of inkjet printing; and vacuum drying the perovskite ink inside a vacuum drying chamber to assemble a perovskite emissive layer in the one at least one sub-pixel.

In one embodiment, the perovskite ink comprises organic metal halide light-emitting perovskite material. In one embodiment, the perovskite ink comprises inorganic metal halide light-emitting perovskite material.

In one embodiment, the profile of the assembled perovskite emissive layer is controlled by varying the rate of vacuum drying of the perovskite ink. In one embodiment, the morphology of the assembled perovskite emissive layer is controlled by varying the rate of vacuum drying of the perovskite ink. In one embodiment, during the step of vacuum drying the perovskite ink, the pressure inside the vacuum drying chamber is reduced to less than or equal to 0.0001 mbar. In one embodiment, during the step of vacuum drying the perovskite ink, the pressure inside the vacuum drying chamber is reduced to less than or equal to 0.0001 mbar in less than or equal to 60 seconds. In one embodiment, during the step of vacuum drying the perovskite ink, the pressure inside the vacuum drying chamber is reduced to less than or equal 0.0001 mbar in less than or equal to 30 seconds. In one embodiment, the duration of the step of vacuum drying the perovskite ink is less than or equal to 120 seconds. In one embodiment, during the step of vacuum drying the perovskite ink, the ambient temperature inside the vacuum drying chamber is 50° C. or less, optionally 30° C. or less.

In one embodiment, the perovskite ink comprises at least one perovskite light emitting material mixed in the at least one solvent at a concentration by weight in the range of 0.01 wt. % to 10 wt. %. In one embodiment, the perovskite ink comprises at least one perovskite light emitting material mixed in the at least one solvent at a concentration by weight in the range of 0.1 wt. % to 5 wt. %. In one embodiment, the thickness of the assembled perovskite emissive layer is in the range of 15 nm to 150 nm.

In one embodiment, the profile of the assembled perovskite emissive layer is controlled by varying the dimensions of the at least one sub-pixel. In one embodiment, the profile of the assembled perovskite emissive layer is controlled by varying the perovskite ink drop volume during the step of depositing the perovskite ink. In one embodiment, the at least one sub-pixel is of length in the range of 100 μm to 250 μm, and of width in the range of 40 μm to 80 μm. In one embodiment, the at least one sub-pixel is of length in the range of 50 μm to 150 μm, and of width in the range of 20 μm to 40 μm. In one embodiment, the at least one sub-pixel is of length in the range of 10 μm and 50 μm, and of width in the range of 5 μm to 20 μm. In one embodiment, the perovskite ink drop volume during the step of depositing the perovskite ink is in the range of 5 pico-liters to 15 pico-liters. In one embodiment, the perovskite ink drop volume during the step of depositing the perovskite ink is in the range of 0.5 pico-liters to 2 pico-liters.

In one embodiment, the profile of the assembled perovskite emissive layer is controlled by varying the number of perovskite ink drops during the step of depositing the perovskite ink. In one embodiment, the total number of perovskite ink drops deposited during the step of depositing the perovskite ink is in the range of 4 perovskite ink drops to 20 perovskite ink drops.

In one embodiment, the profile of the assembled perovskite emissive layer is controlled by varying the angle of the bank structure at the edge of the at least one sub-pixel. In one embodiment, the bank structure is provided at an angle in the range of 30° to 60° at the edge of the at least one sub-pixel. In one embodiment, the profile of the assembled perovskite emissive layer is controlled by varying the surface energy of the bank structure.

In one embodiment, the step of depositing the perovskite ink is performed in an atmosphere of air. In one embodiment, the step of depositing the perovskite ink is performed in an atmosphere of nitrogen.

In one embodiment, after the step of vacuum drying the perovskite ink inside a vacuum drying chamber to assemble a perovskite emissive layer in the at least one sub-pixel, the method further comprises a step of annealing the perovskite emissive layer. In one embodiment, during the step of annealing the perovskite emissive layer, the annealing temperature is in the range of 80° C. to 200° C. In one embodiment, the step of annealing the perovskite emissive layer is performed in an atmosphere of nitrogen. In one embodiment, the step of annealing the perovskite emissive layer is performed in a different chamber to the step of vacuum drying the perovskite ink inside a vacuum drying chamber to assemble a perovskite emissive layer in the at least one sub-pixel.

A perovskite emissive layer is provided. In one embodiment, the perovskite emissive layer is assembled by the disclosed method comprising the steps of: providing a substrate; providing a bank structure disposed over the substrate, wherein the bank structure is patterned so as to define at least one sub-pixel on the substrate; providing a perovskite ink, wherein the perovskite ink comprises at least one solvent and at least one perovskite light emitting material mixed in the at least one solvent; depositing the perovskite ink into the at least one sub-pixel using a method of inkjet printing; and vacuum drying the perovskite ink inside a vacuum drying chamber to assemble a perovskite emissive layer in the at least one sub-pixel.

A perovskite light emitting device is provided. In one embodiment, the perovskite light emitting device comprises a perovskite emissive layer assembled by the disclosed method comprising the steps of: providing a substrate; providing a bank structure disposed over the substrate, wherein the bank structure is patterned so as to define at least one sub-pixel on the substrate; providing a perovskite ink, wherein the perovskite ink comprises at least one solvent and at least one perovskite light emitting material mixed in the at least one solvent; depositing the perovskite ink into the at least one sub-pixel using a method of inkjet printing; and vacuum drying the perovskite ink inside a vacuum drying chamber to assemble a perovskite emissive layer in the at least one sub-pixel.

### DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing. Embodiments of the present disclosure will now be described, by way of example only, with reference to the following:

FIG. 1 depicts 3D perovskite light emitting material with structure ABX₃.

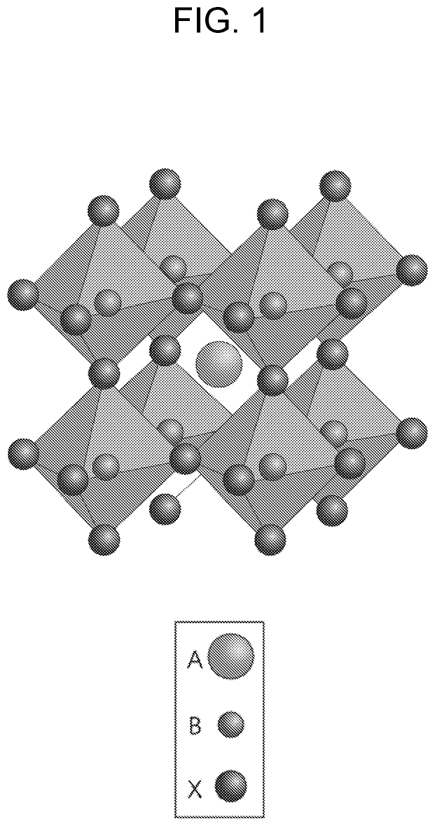

FIG. 2 depicts layered perovskite light emitting material with structure L₂(ABX₃)ₙ₋₁BX₄, where n=1, 3, 5, 10 and ∞.

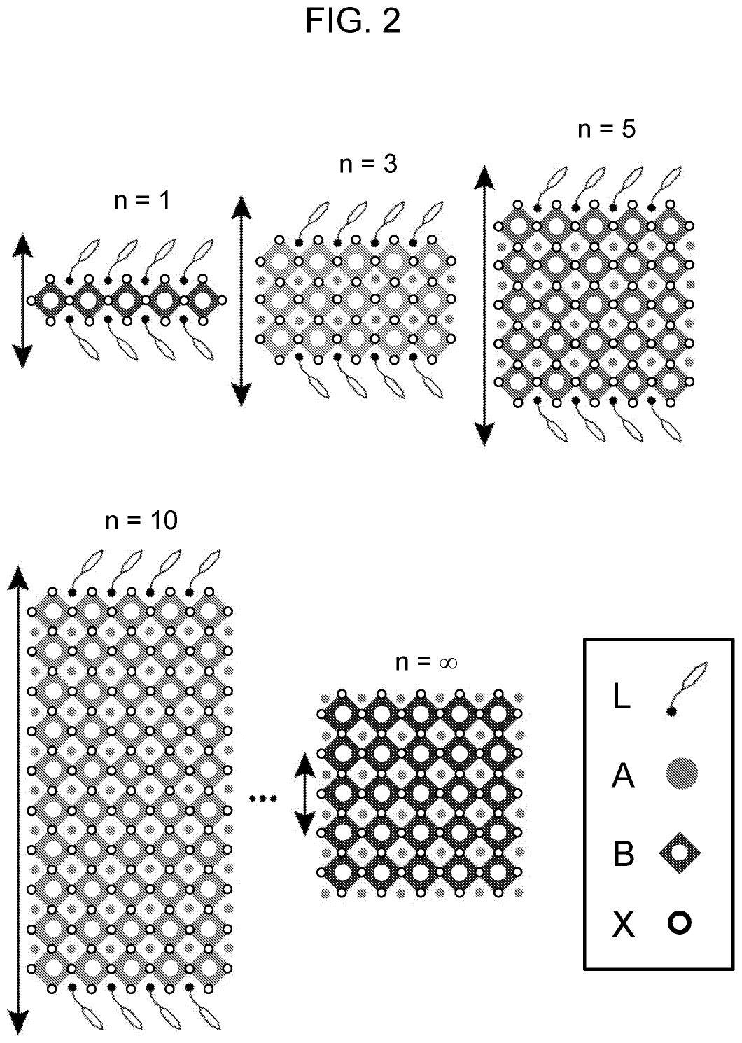

FIG. 3 depicts an example of a nanocrystal of perovskite material with a layered structure that resembles L₂(ABX₃)ₙ₋₁BX₄, where n=5.

FIG. 4 depicts a standard perovskite light emitting device.

FIG. 5 depicts an inverted perovskite light emitting device.

FIG. 6 depicts a rendition of the CIE 1931 (x, y) colour space chromaticity diagram.

FIG. 7 depicts a rendition of the CIE 1931(x, y) colour space chromaticity diagram that also shows colour gamut for (a) DCI-P3 and (b) Rec. 2020 colour spaces

FIG. 8 depicts a rendition of the CIE 1931 (x, y) colour space chromaticity diagram that also shows colour gamut for (a) DCI-P3 and (b) Rec. 2020 colour spaces with colour coordinates for exemplary red, green and blue PeLED and OLED devices

FIG. 9 depicts exemplary electroluminescence emission spectra for red, green and blue PeLED and OLED devices.

FIG. 10 depicts a process flow for a method of assembling a perovskite emissive layer.

FIG. 11 depicts exemplary vacuum drying curves.

FIG. 12 depicts the assembly of a perovskite emissive layer from a perovskite ink.

FIG. 13 depicts exemplary designs of sub-pixels.

FIG. 14 depicts a cross-section of a bank structure.

### DESCRIPTION OF EMBODIMENTS

General device architectures and operating principles for PeLEDs are substantially similar to those for OLEDs. Both of these light emitting devices comprises at least one emissive layer disposed between and electrically connected to an anode and a cathode. For a PeLED, the emissive layer comprises perovskite light emitting material. For an OLED, the emissive layer comprises organic light emitting material. For both of these light emitting devices, when a current is applied, the anode injects holes and the cathode injects electrons into the emissive layer(s). The injected holes and electrons each migrate towards the oppositely charged electrode. When an electron and a hole localize, an exciton, which is a localized electron-hole pair having an excited energy state, may be formed. Light is emitted if the exciton relaxes via a photo-emissive mechanism. Non-radiative mechanisms, such as thermal radiation and/or Auger recombination may also occur, but are generally considered undesirable.

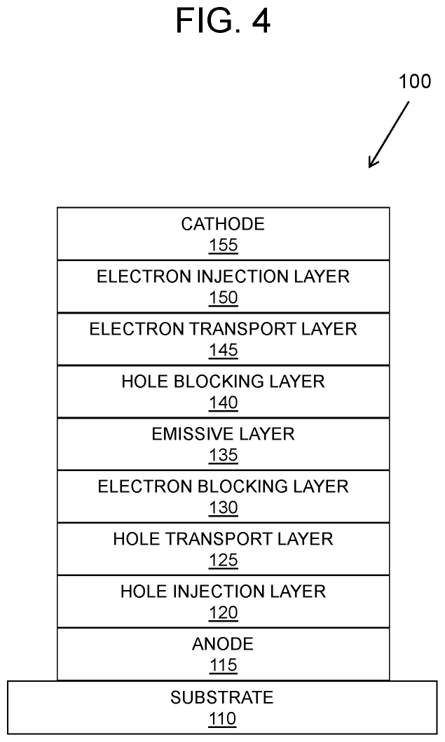

FIG. 4 shows a light emitting device 100 comprising a single emissive layer. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150 and a cathode 155. The emissive layer 135 may comprise perovskite light emitting material. Device 100 may be fabricated by depositing the layers described in order. As the device 100 has anode 115 disposed under cathode 155, device 100 may be referred to as a “standard” device architecture. If the device were orientated differently, with the cathode 155 disposed under the anode 115, then the device would instead be referred to as an “inverted device architecture.

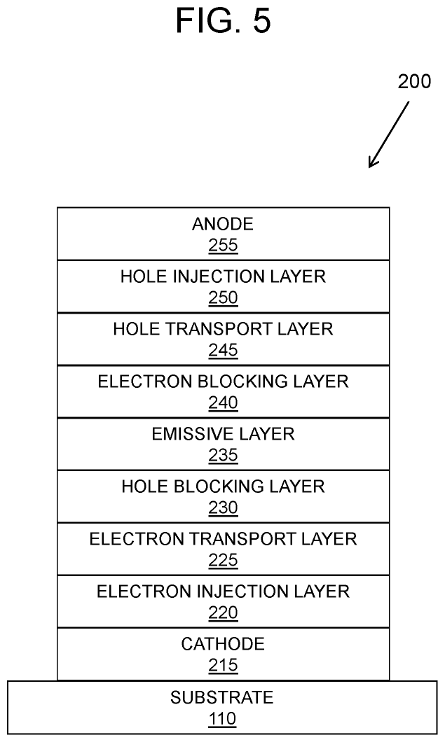

FIG. 5 shows an inverted light emitting device 200 comprising a single emissive layer. Device 200 may include a substrate 110, a cathode 215, an electron injection layer 220, an electron transport layer 225, a hole blocking layer 230, an emissive layer 235, an electron blocking layer 240, a hole transport layer 245, a hole injection layer 250 and an anode 255. The emissive layer 235 may comprise perovskite light emitting material. Device 200 may be fabricated by depositing the layers described in order.

The simple layered structures illustrated in FIGS. 4 and 5 are provided by way of non-limiting examples, and it is understood that embodiments of the invention may be used in connection with a wide variety of other structures. The specific materials and structures described are exemplary in nature, and other materials and structures may be used. Functional PeLEDs may be achieved by combining the various layers described in different ways, or layers may be omitted entirely, based on factors such as performance, design and cost. Other layers, not specifically described, may also be included. Materials other than those specifically described may be used. Although many of the examples provided herein describe various layers as comprising a single material, it is understood that combinations of materials may be used. Also, the layers may have various sublayers. The names given to the various layers herein are not intended to be strictly limiting. For example, in a device, the hole transport layer may transport and inject holes into the emissive layer and may be described as a hole transport layer or a hole injection layer. For example, in a device, the hole blocking layer may block holes and transport electrons and may be described as a hole blocking layer or an electron transport layer.

PeLEDs are generally intended to emit light through at least one of the electrodes, and one or more transparent electrodes may be useful in such optoelectronic devices. For example, a transparent electrode material, such as indium tin oxide (ITO), may be used for the bottom electrode, while a transparent electrode material, such as a thin metallic layer of a blend of magnesium and silver (Mg:Ag), may be used for the top electrode. For a device intended to emit light only through the bottom electrode, the top electrode does not need to be transparent, and may be comprised of an opaque and/or reflective layer, such as a metal layer having a high reflectivity. Similarly, for a device intended only to emit light through the top electrode, the bottom electrode may be opaque and/or reflective, such as a metal layer having a high reflectivity. Where an electrode does not need to be transparent, using a thicker layer may provide better conductivity and may reduce voltage drop and/or Joule heating in the device, and using a reflective electrode may increase the amount of light emitted through the other electrode by reflecting light back towards the transparent electrode. A fully transparent device may also be fabricated, where both electrodes are transparent.

With reference to device 100 in FIG. 4, devices fabricated in accordance with embodiments of the present invention may optionally comprise a substrate 110. The substrate 110 may comprise any suitable material that provides the desired structural and optical properties. The substrate 110 may be rigid or flexible. The substrate 110 may be flat or curved. The substrate 110 may be transparent, translucent or opaque. Preferred substrate materials are glass, plastic and metal foil. Other substrates, such as fabric and paper may be used. The material and thickness of the substrate 110 may be chosen to obtain desired structural and optical properties.

With reference to device 100 in FIG. 4, devices fabricated in accordance with embodiments of the present invention may optionally comprise an anode 115. The anode 115 may comprise any suitable material or combination of materials known to the art, such that the anode 115 is capable of conducting holes and injecting them into the layers of the device. Preferred anode 115 materials include conductive metal oxides, such as indium tin oxide (ITO), indium zinc oxide (IZO) and aluminum zinc oxide (AlZnO), metals such as silver (Ag), aluminum (Al), aluminum-neodymium (Al:Nd), gold (Au) and alloys thereof, or a combination thereof. Other preferred anode 115 materials include graphene, carbon nanotubes, nanowires or nanoparticles, silver nanowires or nanoparticles, organic materials, such as poly(3,4-ethylenedioxythiophene): polystyrene sulfonate (PEDOT:PSS) and derivatives thereof, or a combination thereof. Compound anodes comprising one or more anode materials in a single layer may be preferred for some devices. Multilayer anodes comprising one or more anode materials in one or more layers may be preferred for some devices. One example of a multilayer anode is ITO/Ag/ITO. In a standard device architecture for PeLEDs, the anode 115 may be sufficiently transparent to create a bottom-emitting device, where light is emitted through the substrate. One example of a transparent anode commonly used in a standard device architecture is a layer of ITO. Another example of a transparent anode commonly used in a standard device architecture is ITO/Ag/ITO, where the Ag thickness is less than approximately 25 nm. By including a layer of silver of thickness less than approximately 25 nm, the anode may be transparent as well as partially reflective. When such a transparent and partially reflective anode is used in combination with a reflective cathode, such as LiF/Al, this may have the advantage of creating a microcavity within the device. A microcavity may provide one or more of the following advantages: an increased total amount of light emitted from device, and therefore higher efficiency and brightness; an increased proportion of light emitted in the forward direction, and therefore increased apparent brightness at normal incidence; and spectral narrowing of the emission spectrum, resulting in light emission with increased colour saturation. The anode 115 may be opaque and/or reflective. In a standard device architecture for PeLEDs, a reflective anode 115 may be preferred for some top-emitting devices to increase the amount of light emitted from the top of the device. One example of a reflective anode commonly used in a standard device architecture is a multilayer anode of ITO/Ag/ITO, where the Ag thickness is greater than approximately 80 nm. When such a reflective anode is used in combination with a transparent and partially reflective cathode, such as Mg:Ag, this may have the advantage of creating a microcavity within the device. The material and thickness of the anode 115 may be chosen to obtain desired conductive and optical properties. Where the anode 115 is transparent, there may be a range of thicknesses for a particular material that is thick enough to provide the desired conductivity, yet thin enough to provide the desired degree of transparency. Other materials and structures may be used.

With reference to device 100 in FIG. 4, devices fabricated in accordance with embodiments of the present invention may optionally comprise a hole transport layer 125. The hole transport layer 125 may include any material capable of transporting holes. The hole transport layer 125 may be deposited by a solution process or by a vacuum deposition process. The hole transport layer 125 may be doped or undoped. Doping may be used to enhance conductivity.

Examples of undoped hole transport layers are N,N′-Di(1-naphthyl)-N,N′-diphenyl-(1,1′-biphenyl)-4,4′-diamine (NPD), poly[(9,9-dioctylfluorenyl-2,7-diyl)-co-(4,4′-(N-(4-sec-butylphenyl) diphenylamine (TFB), poly[N,N′-bis(4-butylphenyl)-N,N′-bis(phenyl)-benzidine] (poly-TPD), poly(9-vinylcarbazole) (PVK), 4,4′-Bis(N-carbazolyl)-1,1′-biphenyl (CBP), Spiro-OMeTAD and molybdenum oxide (MoO₃). One example of a doped hole transport layer is 4,4′,4″-Tris[phenyl(m-tolyl)amino]triphenylamine (m-MTDATA) doped with F₄-TCNQ at a molar ratio of 50:1. One example of a solution-processed hole transport layer is PEDOT:PSS. Other hole transport layers and structures may be used. The preceding examples of hole transport materials are especially well-suited to application in PeLEDs.

With reference to device 100 in FIG. 4, devices fabricated in accordance with embodiments of the present invention may optionally comprise one or more emissive layers 135. The emissive layer 135 may include any perovskite material capable of emitting light when a current is passed between anode 115 and cathode 155. The emissive layer of a PeLED may comprise perovskite light emitting material.

Examples of perovskite light-emitting materials include 3D perovskite materials, such as methylammonium lead iodide (CH₃NH₃PbI₃), methylammonium lead bromide (CH₃NH₃PbBr₃), methylammonium lead chloride (CH₃NH₃PbCl₃), formamidinium lead iodide (CH(NH₂)₂PbI₃), formamidinium lead bromide (CH(NH₂)₂PbBr₃), formamidinium lead chloride (CH(NH₂)₂PbCl₃), caesium lead iodide (CsPbI₃), caesium lead bromide (CsPbBr₃) and caesium lead chloride (CsPbCl₃). Examples of perovskite light-emitting materials further include 3D perovskite materials with mixed halides, such as CH₃NH₃PbI₃₋ₓClₓ, CH₃NH₃PbI₃₋ₓBrₓ, CH₃NH₃PbCl₃₋ₓBrₓ, CH(NH₂)₂PbI₃₋ₓBrₓ, CH(NH₂)₂PbI₃₋ₓClₓ, CH(NH₂)₂PbCl₃₋ₓBrₓ, CsPbI₃₋ₓClₓ, CsPbI₃₋ₓBrₓ and CsPbCl₃₋ₓBrₓ, where x is in the range of 0-3. Examples of perovskite light-emitting materials further include 2D perovskite materials such as (C₁₀H₇CH₂NH₃)₂PbI₄, (C₁₀H₇CH₂NH₃)₂PbBr₄, (C₁₀H₇CH₂NH₃)₂PbCl₄, (C₆H₅C₂H₄NH₃)₂PbI₄, (C₆H₅C₂H₄NH₃)₂PbBr₄ and (C₆H₅C₂H₄NH₃)₂PbCl₄, 2D perovskite materials with mixed halides, such as (C₁₀H₇CH₂NH₃)₂PbI₃₋ₓClₓ, (C₁₀H₇CH₂NH₃)₂PbI₃₋ₓBrₓ, (C₁₀H₇CH₂NH₃)₂PbCl₃₋ₓBrₓ, (C₆H₅C₂H₄NH₃)₂PbI₃₋ₓClₓ, (C₆H₅C₂H₄NH₃)₂PbI₃₋ₓBrₓ and (C₆H₅C₂H₄NH₃)₂PbCl₃₋ₓBrₓ, where x is in the range of 0-3. Examples of perovskite light-emitting materials further include Quasi-2D perovskite materials, such as (C₆H₅C₂H₄NH₃)₂(CH(NH₂)₂PbBr₃)ₙ₋₁PbI₄, (C₆H₅C₂H₄NH₃)₂(CH(NH₂)₂PbBr₃)ₙ₋₁PbBr₄, (C₆H₅C₂H₄NH₃)₂(CH(NH₂)₂PbBr₃)ₙ₋₁PbCl₄, (C₁₀H₇CH₂NH₃)₂(CH₃NH₃PbI₂Br)ₙ₋₁PbI₄, (C₁₀H₇CH₂NH₃)₂(CH₃NH₃PbI₂Br)ₙ₋₁PbBr₄ and (C₁₀H₇CH₂NH₃)₂(CH₃NH₃PbI₂Br)ₙ₋₁PbCl₄, where n is the number of layers, and, optionally, n may be in the range of about 2-10. Examples of perovskite light-emitting materials further include Quasi-2D perovskite materials with mixed halides, such as (C₆H₅C₂H₄NH₃)₂(CH(NH₂)₂PbBr₃)ₙ₋₁PbI₃₋ₓClₓ, (C₆H₅C₂H₄NH₃)₂(CH(NH₂)₂PbBr₃)ₙ₋₁PbI₃₋ₓBrₓ, (C₆H₅C₂H₄NH₃)₂(CH(NH₂)₂PbBr₃)ₙ₋₁PbCl₃₋ₓBrₓ, (C₁₀H₇CH₂NH₃)₂(CH₃NH₃PbI₂Br)ₙ₋₁PbI₃₋ₓClₓ, (C₁₀H₇CH₂NH₃)₂(CH₃NH₃PbI₂Br)ₙ₋₁PbI₃₋ₓBrₓ and (C₁₀H₇CH₂NH₃)₂(CH₃NH₃PbI₂Br)ₙ₋₁PbCl₃₋ₓBrₓ, where n is the number of layers, and, optionally, n may be in the range of about 2-10, and x is in the range of 0-3. Examples of perovskite light-emitting materials further include any of the aforementioned examples, where the divalent metal cation lead (Pb⁺) may be replaced with tin (Sn⁺), copper (Cu⁺) or europium (Eu⁺). Examples of perovskite light-emitting materials further include perovskite light-emitting nanocrystals with structures that closely resemble Quasi-2D perovskite materials.

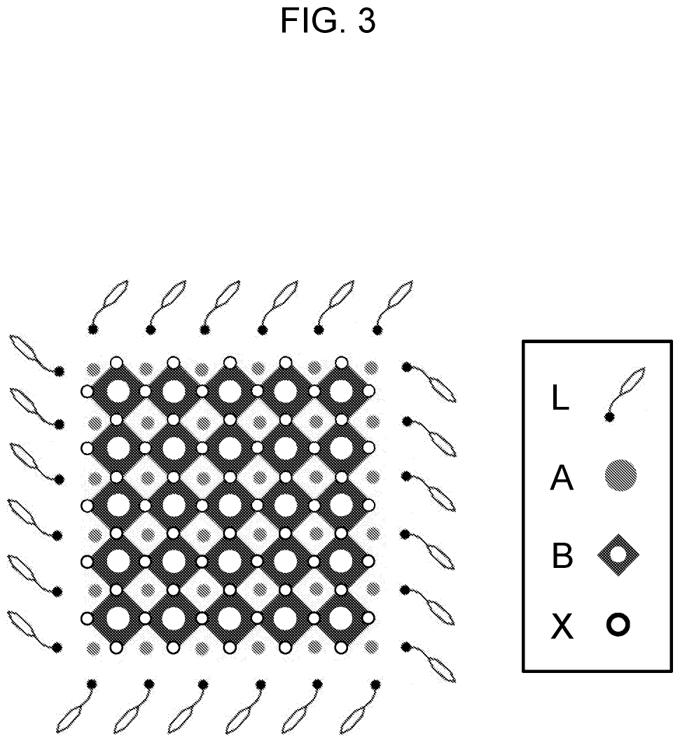

Perovskite light emitting material may comprise organic metal halide perovskite material, such as methylammonium lead iodide (CH₃NH₃PbI₃), methylammonium lead bromide (CH₃NH₃PbBr₃), methylammonium lead chloride (CH₃NH₃PbCl₃), where the materials comprises an organic cation. Perovskite light emitting material may comprise inorganic metal halide perovskite material, such as caesium lead iodide (CsPbI₃), caesium lead bromide (CsPbBr₃) and caesium lead chloride (CsPbCl₃), where the material comprises an inorganic cation. Furthermore, perovskite light emitting material may comprise perovskite light emitting material where there is a combination of organic and inorganic cations. The choice of an organic or inorganic cation may be determined by several factors, including desired emission colour, efficiency of electroluminescence, stability of electroluminescence and ease of processing. Inorganic metal halide perovskite material may be particularly well-suited to perovskite light-emitting materials with a nanocrystal structure, such as those depicted in FIG. 3, wherein an inorganic cation may enable a compact and stable perovskite light-emitting nanocrystal structure.

Perovskite light emitting material may be included in the emissive layer 135 in a number of ways. For example, the emissive layer may comprise 2D perovskite light-emitting material, Quasi-2D perovskite light-emitting material or 3D perovskite light-emitting material, or a combination thereof. Optionally, the emissive layer may comprise perovskite light emitting nanocrystals. Optionally, the emissive layer 135 may comprise an ensemble of Quasi-2D perovskite light emitting materials, where the Quasi-2D perovskite light emitting materials in the ensemble may comprise a different number of layers. An ensemble of Quasi-2D perovskite light emitting materials may be preferred because there may be energy transfer from Quasi-2D perovskite light emitting materials with a smaller number of layers and a larger energy band gap to Quasi-2D perovskite light emitting materials with a larger number of layers and a lower energy band gap. This energy funnel may efficiently confine excitons in a PeLED device and may improve device performance. Optionally, the emissive layer 135 may comprise perovskite light emitting nanocrystal materials. Perovskite light emitting nanocrystal materials may be preferred because nanocrystal boundaries may be used to confine excitons in a PeLED device, and surface cations may be used to passivate the nanocrystal boundaries. This exciton confinement and surface passivation may improve device performance. Other emissive layer materials and structures may be used.

With reference to device 100 in FIG. 4, devices fabricated in accordance with embodiments of the present invention may optionally comprise an electron transport layer 145. The electron transport layer 145 may include any material capable of transporting electrons. The electron transport layer 145 may be deposited by a solution process or by a vacuum deposition process. The electron transport layer 145 may be doped or undoped. Doping may be used to enhance conductivity.

Examples of undoped electron transport layers are tris(8-hydroxyquinolinato)aluminum (Alq₃), 2,2′,2″-(1,3,5-Benzinetriyl)-tris(1-phenyl-1-H-benzimidazole) (TPBi), 2,9-Dimethyl-4,7-diphenyl-1,10-phenanthroline (BCP), zinc oxide (ZnO) and titanium dioxide (TiO₃). One example of a doped electron transport layer is 4,7-diphenyl-1,10-phenanthroline (BPhen) doped with lithium (Li) at a molar ratio of 1:1. One example of a solution-processed electron transport layer is [6,6]-Phenyl C61 butyric acid methyl ester (PCBM). Other electron transport layers and structures may be used. The preceding examples of electron transport materials are especially well-suited to application in PeLEDs.

With reference to device 100 in FIG. 4, devices fabricated in accordance with embodiments of the present invention may optionally comprise a cathode 155. The cathode 155 may comprise any suitable material or combination of materials known to the art, such that the cathode 155 is capable of conducting electronics and injecting them into the layers of the device. Preferred cathode 155 materials include metal oxides, such as indium tin oxide (ITO), indium zinc oxide (IZO) and fluorine tin oxide (FTO), metals, such as calcium (Ca), barium (Ba), magnesium (Mg) and ytterbium (Yb) or a combination thereof. Other preferred cathode 155 materials include metals such as silver (Ag), aluminum (Al), aluminum-neodymium (Al:Nd), gold (Au) and alloys thereof, or a combination thereof. Compound cathodes comprising one or more cathode materials in a single layer may be preferred from some devices. One example of a compound cathode is Mg:Ag. Multilayer cathodes comprising one or more cathode materials in one or more layers may be preferred for some devices. One example of a multilayer cathode is Ba/Al. In a standard device architecture for PeLEDs, the cathode 155 may be sufficiently transparent to create a top-emitting device, where light is emitted from the top of the device. One example of a transparent cathode commonly used in a standard device architecture is a compound layer of Mg:Ag. By using a compound of Mg:Ag, the cathode may be transparent as well as partially reflective. When such a transparent and partially reflective cathode is used in combination with a reflective anode, such as ITO/Ag/ITO, where the Ag thickness is greater than approximately 80 nm, this may have the advantage of creating a microcavity within the device. The cathode 155 may be opaque and/or reflective. In a standard device architecture for PeLEDs, a reflective cathode 155 may be preferred for some bottom-emitting devices to increase the amount of light emitted through the substrate from the bottom of the device. One example of a reflective cathode commonly used in a standard device architecture is a multilayer cathode of LiF/Al. When such a reflective cathode is used in combination with a transparent and partially reflective anode, such as ITO/Ag/ITO, where the Ag thickness is less than approximately 25 nm, this may have the advantage of creating a microcavity within the device.

The material and thickness of the cathode 155 may be chosen to obtain desired conductive and optical properties. Where the cathode 155 is transparent, there may be a range of thicknesses for a particular material that is thick enough to provide the desired conductivity, yet thin enough to provide the desired degree of transparency. Other materials and structures may be used.

With reference to device 100 in FIG. 4, devices fabricated in accordance with embodiments of the present invention may optionally comprise one or more blocking layers. Blocking layers may be used to reduce the number of charge carriers (electrons or holes) and/or excitons exiting the emissive layer. An electron blocking layer 130 may be disposed between the emissive layer 135 and the hole transport layer 125 to block electrons from leaving the emissive layer 135 in the direction of the hole transport layer 125. Similarly, a hole blocking layer 140 may be disposed between the emissive layer 135 and the electron transport layer 145 to block holes from leaving the emissive layer 135 in the direction of the electron transport layer 145. Blocking layers may also be used to block excitons from diffusing from the emissive layer. As used herein, and as would be understood by one skilled in the art, the term “blocking layer” means that the layer provides a barrier that significantly inhibits transport of charge carriers and/or excitons, without suggesting that the layer completely blocks the charge carriers and/or excitons.

The presence of such a blocking layer in a device may result in substantially higher efficiencies as compared to a similar device lacking a blocking layer. A blocking layer may also be used to confine emission to a desired region of a device.

Devices fabricated in accordance with embodiments of the present invention may optionally comprise one or more injection layers. Generally, injection layers are comprised of one or more materials that may improve the injection of charge carriers from one layer, such as an electrode, into an adjacent layer. Injection layers may also perform a charge transport function.

In device 100, the hole injection layer 120 may be any layer that improves the injection of holes from the anode 115 into the hole transport layer 125. Examples of materials that may be used as a hole injection layer are Copper(II)phthalocyanine (CuPc) and 1,4,5,8,9,11-Hexaazatriphenylenehexacarbonitrile (HATCN), which may be vapor deposited, and polymers, such as PEDOT:PSS, which may be deposited from solution. Another example of a material that may be used as a hole injection layer is molybdenum oxide (MoO₃). The preceding examples of hole injection materials are especially well-suited to application in PeLEDs.

A hole injection layer (HIL) 120 may comprise a charge carrying component having HOMO energy level that favourably matches, as defined by their herein-described relative IP energies, with the adjacent anode layer on one side of the HIL, and the hole transporting layer on the opposite side of the HIL. The “charge carrying component” is the material responsible for the HOMO energy level that actually transports the holes. This material may be the base material of the HIL, or it may be a dopant. Using a doped HIL allows the dopant to be selected for its electrical properties, and the host to be selected for morphological properties, such as ease of deposition, wetting, flexibility, toughness, and others. Preferred properties of the HIL material are such that holes can be efficiently injected from the anode into the HIL material. The charge carrying component of the HIL 120 preferably has an IP not more than about 0.5 eV greater than the IP of the anode material. Similar conditions apply to any layer into which holes are being injected. HIL materials are further distinguished from conventional hole transporting materials that are typically used in the hole transporting layer of a PeLED in that such HIL materials may have a hole conductivity that is substantially less than the hole conductivity of conventional hole transporting materials. The thickness of the HIL 120 of the present invention may be thick enough to planarize the anode and enable efficient hole injection, but thin enough not to hinder transportation of holes. For example, an HIL thickness of as little as 10 nm may be acceptable. However, for some devices, an HIL thickness of up to 80 nm may be preferred.

In device 100, the electron injection layer 150 may be any layer that improves the injection of electrons from the cathode 155 into the electron transport layer 145. Examples of materials that may be used as an electron injection layer are inorganic salts, such as lithium fluoride (LiF), sodium fluoride (NaF), barium fluoride (BaF), caesium fluoride (CsF), and caesium carbonate (CsCO₃). Other examples of materials that may be used as an electron injection layer are metal oxides, such as zinc oxide (ZnO) and titanium oxide (TiO₂), and metals, such as calcium (Ca), barium (Ba), magnesium (Mg) and ytterbium (Yb). Other materials or combinations of materials may be used for injection layers. Depending on the configuration of a particular device, injection layers may be disposed at locations different than those shown in device 100. The preceding examples of electron injection materials are all especially well-suited to application in PeLEDs.

Unless otherwise specified, any one of the layers of the various embodiments may be deposited by any suitable method. Methods include vapor deposition processes, such as vacuum thermal evaporation, sputtering, electron beam physical vapour deposition, organic vapor phase deposition and organic vapour jet printing. Other suitable methods include solution-based processes, including spincoating and inkjet printing.

Devices fabricated in accordance with embodiments of the invention may be incorporated into a wide range of consumer products. Optionally, devices may be used in displays for televisions, computer monitors, tablets, laptop computers, smart phones, cell phones, digital cameras, video recorders, smartwatches, fitness trackers, personal digital assistants, vehicle displays and other electronic devices. Optionally, devices may be used for micro-displays or heads-up displays. Optionally, devices may be used in light panels for interior or exterior illumination and/or signaling, in smart packaging or in billboards.

Optionally, various control mechanisms may be used to control light emitting devices fabricated in accordance with the present invention, including passive matrix and active matrix address schemes.

The materials and structures described herein may have applications in devices other than light emitting devices. For example, other optoelectronic devices such as solar cells, photodetectors, transistors or lasers may employ the materials and structures.

Layers, materials, regions, units and devices may be described herein in reference to the colour of light they emit. As used herein, a “red” layer, material, region, unit or device, refers to one that emits light that has an emission spectrum with a peak wavelength in the range of about 580-780 nm; a “green” layer, material, region, unit or device, refers to one that emits light that has an emission spectrum with a peak wavelength in the range of about 500-580 nm; a “blue” layer, material, region, unit or device, refers to one that emits light that has an emission spectrum with a peak wavelength in the range of about 380-500 nm. Preferred ranges include a peak wavelength in the range of about 600-640 nm for red, about 510-550 nm for green, and about 440-465 nm for blue.

Display technology is rapidly evolving, with recent innovations enabling thinner and lighter displays with higher resolution, improved frame rate and enhanced contrast ratio. However, one area where significant improvement is still required is colour gamut.

Digital displays are currently incapable of producing many of the colours the average person experiences in day-to-day life. To unify and guide the industry towards improved colour gamut, two industry standards have been defined, DCI-P3 and Rec. 2020, with DCI-P3 often seen as a stepping stone towards Rec. 2020.

DCI-P3 was defined by the Digital Cinema Initiatives (DCI) organization and published by the Society of Motion Picture and Television Engineers (SMPTE). Rec. 2020 (more formally known as ITU-R Recommendation BT. 2020) was developed by the International Telecommunication Union to set targets, including improved colour gamut, for various aspects of ultra-high-definition televisions.

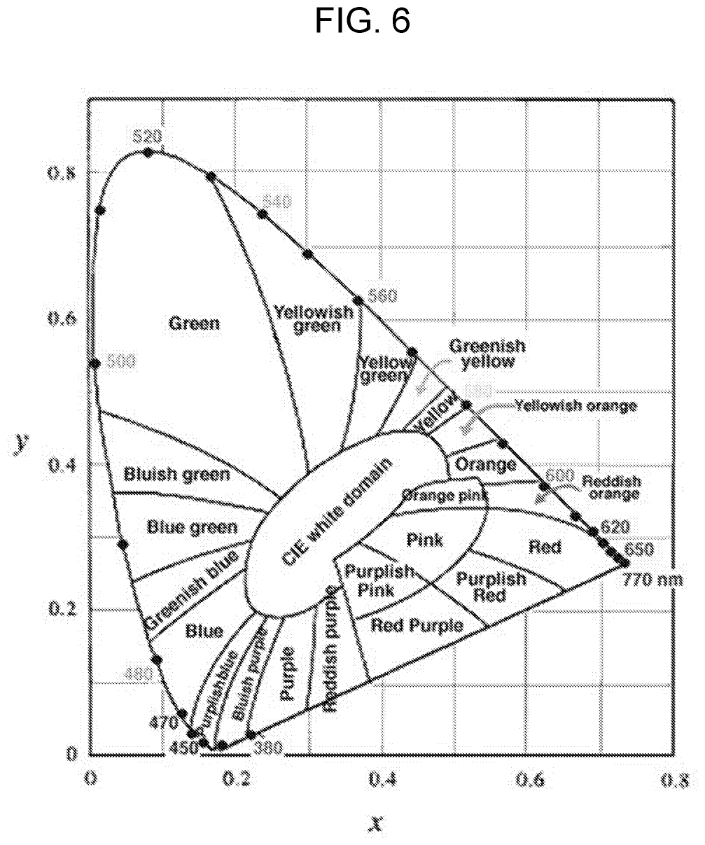

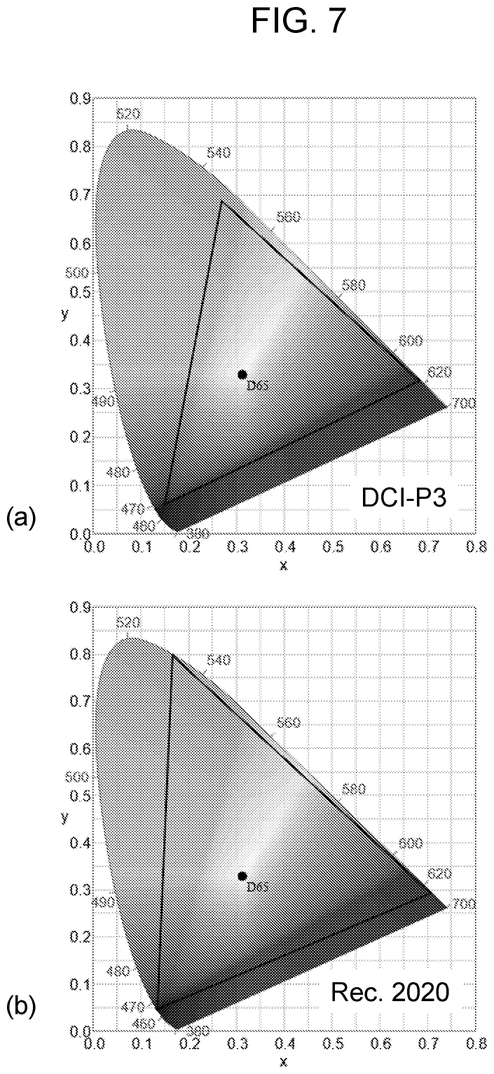

The CIE 1931 (x, y) chromaticity diagram was created by the Commission Internationale de l'Eclairage (CIE) in 1931 to define all colour sensations that an average person can experience. Mathematical relationships describe the location of each colour within the chromaticity diagram. The CIE 1931 (x, y) chromaticity diagram may be used to quantify the colour gamut of displays. The white point (D65) is at the centre, while colours become increasingly saturated (deeper) towards the extremities of the diagram. FIG. 6 shows the CIE 1931 (x, y) chromaticity diagram with labels added to different locations on the diagram to enable a general understanding of distribution of colour within the colour space. FIG. 7 shows (a) DCI-P3 and (b) Rec. 2020 colour spaces superimposed on the CIE 1931 (x, y) chromaticity diagram. The tips of the triangles are primary colours for DCI-P3 and Rec. 2020, respectively, while colours enclosed within the triangles are all the colours that can be reproduced by combining these primary colours. For a display to meet DCI-P3 colour gamut specifications, the red, green and blue sub-pixels of the display must emit light at least as deep in colour as the DCI-P3 primary colours. For a display to meet Rec. 2020 colour gamut specifications, the red, green and blue sub-pixels of the display must emit light at least as deep in colour as the Rec. 2020 primary colours. Primary colours for Rec. 2020 are significantly deeper than for DCI-P3, and therefore achievement of the Rec. 2020 standard for colour gamut is seen as a greater technical challenge than achieving the DCI-P3 standard.

Commercial OLED displays can successfully render the DCI-P3 colour gamut. For example, smartphones with OLED displays such as the iPhone X (Apple), Galaxy S9 (Samsung) and OnePlus 5 (OnePlus) can all render the DCI-P3 gamut. Commercial liquid crystal displays (LCDs) can also successfully render the DCI-P3 colour gamut. For example, LCDs in the Surface Studio (Microsoft), Mac Book Pro and iMac Pro (both Apple) can all render the DCI-P3 gamut. However, until now, no display has been demonstrated that can render the Rec. 2020 colour gamut.

Here we disclose a novel method of assembling a perovskite emissive layer. In various embodiments, when implemented in a perovskite light emitting device, the perovskite emissive layer assembled by the disclosed method may enable the perovskite light emitting device to render a primary colour of the DCI-P3 colour gamut. In various embodiments, when implemented in a perovskite light emitting device, the perovskite emissive layer assembled by the disclosed method may enable the perovskite light emitting device to render a primary colour of the Rec. 2020 colour gamut.

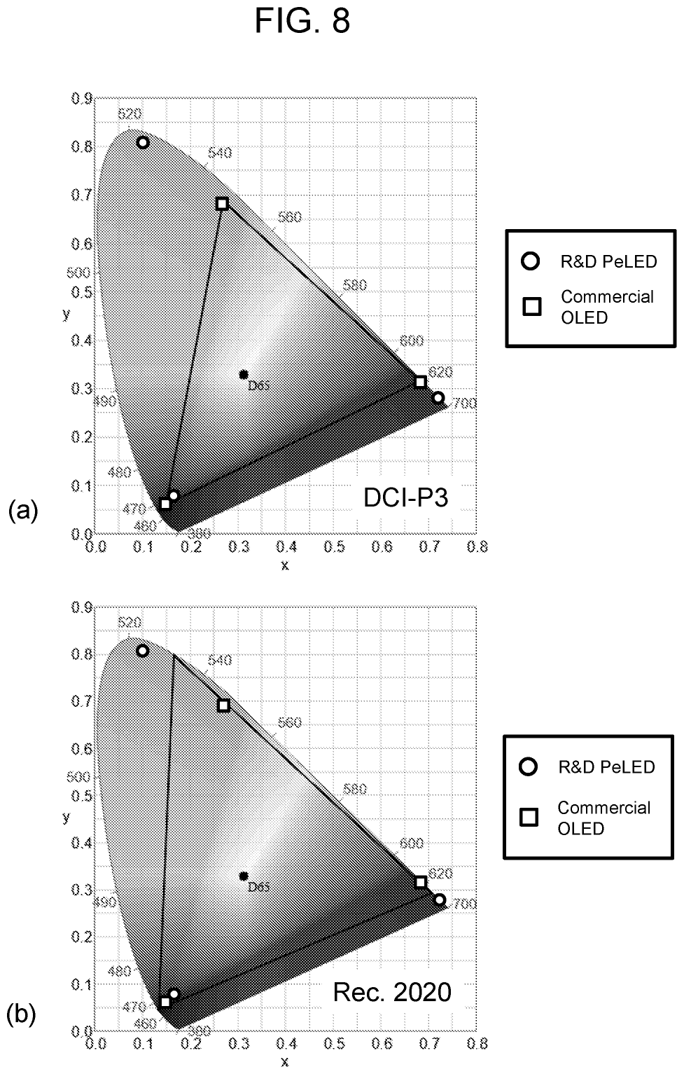

One or more advantages of assembling a perovskite emissive layer for application in a perovskite light emitting device may be demonstrated using the data shown in Table 1 and FIG. 8. Table 1 shows CIE 1931 (x, y) colour coordinates for single emissive layer red, green and blue R&D PeLED and Commercial OLED devices. Also included in Table 1 are CIE 1931 (x, y) colour coordinates for DCI-P3 and Rec. 2020 colour gamut standards. Generally, for red light, a higher CIE x value corresponds to deeper emission colour, for green light, a higher CIE y value corresponds to deeper emission colour, and for blue light, a lower CIE y value corresponds to deeper emission colour. This can be understood with reference FIG. 8, which includes markers for the red, green and blue R&D PeLED (circles) and Commercial OLED (squares) device data in Table 1, as well as markers for the primary colours of the DCI-P3 colour gamut in FIG. 8a and for the Rec. 2020 colour gamut in FIG. 8b.

TABLE 1
CIE 1931 (x, y) colour coordinates for exemplary single
emissive layer R&D PeLED and Commercial OLED
devices. Also included are colour coordinates for
DCI-P3 and Rec. 2020 colour gamut standards.

| | Red | | Green | | Blue | |
|---|---|---|---|---|---|---|
| | CIE x | CIE y | CIE x | CIE y | CIE x | CIE y |
| DCI-P3 | 0.680 | 0.320 | 0.265 | 0.690 | 0.150 | 0.060 |
| Rec. 2020 | 0.708 | 0.292 | 0.170 | 0.797 | 0.131 | 0.046 |
| Commercial | 0.680 | 0.320 | 0.265 | 0.690 | 0.150 | 0.060 |
| OLED | | | | | | |
| R&D PeLED | 0.720 | 0.280 | 0.100 | 0.810 | 0.166 | 0.079 |

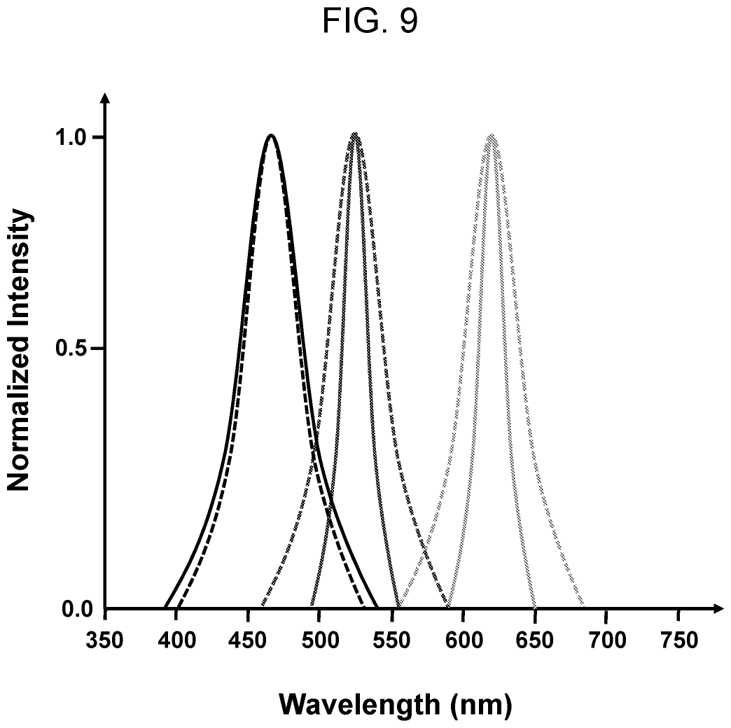

FIG. 9 depicts exemplary electroluminescence emission spectra for single emissive layer red, green and blue R&D PeLEDs and Commercial OLEDs. The red, green and blue spectra depicted using dashed lines correspond to spectra for Commercial OLED devices, such as those in the Apple iPhone X, which may be used to render the DCI-P3 colour gamut. The red, green and blue spectra depicted using solid lines correspond to spectra for R&D PeLED devices. The electroluminescence spectra for red, green and blue R&D PeLED devices depicted using solid lines in FIG. 9 demonstrate that red and green R&D PeLED devices may render deeper red and green colours than Commercial OLED devices, but that further development is needed for blue R&D PeLED devices to render deeper blue colours than Commercial OLED devices.

The CIE 1931 (x, y) colour coordinate data reported for single emissive layer red, green and blue R&D PeLED and Commercial OLED devices in Table 1 are exemplary. Commercial OLED data are taken from the Apple iPhone X, which fully supports the DCI-P3 colour gamut. This data set is available from Raymond Soneira at DisplayMate Technologies Corporation (Soneira et al.). Data for R&D PeLED devices are taken from a selection of peer-reviewed scientific journals: Red R&D PeLED data are taken from Wang et al. Green R&D PeLED data are taken from Hirose et al. Blue R&D PeLED data are taken from Kumar et al. Data from these sources are used by way of example, and should be considered non-limiting. Data from other peer-reviewed scientific journals, simulated data and/or experimental data collected from laboratory devices may also be used to demonstrate the aforementioned advantages of implementing a perovskite light emitting layer assembled using the disclosed method in a perovskite light emitting device.

As can be seen from Table 1 and FIG. 8a, existing organic light emitting materials and devices can already be used to demonstrate a commercial display that can render the DCI-P3 colour gamut, as is exemplified by the Apple iPhone X. However, as can be seen from FIG. 8b, existing organic light emitting materials and devices alone cannot be used to demonstrate a display that can render the Rec. 2020 colour gamut. Table 1 and FIG. 8b show that one path to demonstrating a display that can render the Rec. 2020 colour gamut is to include one or more perovskite emissive layers in one or more perovskite light emitting devices in one or more sub-pixels of a display.

Optionally, by including one or more perovskite emissive layers in a perovskite light emitting device, the device may emit red light with CIE 1931 (x, y)=(0.720, 0.280), which as can be seen from FIG. 8b, is more saturated than the red primary color for the Rec. 2020 standard, which has CIE 1931 (x, y)=(0.708, 0.292).

Optionally, by including one or more perovskite emissive layers in a perovskite light emitting device, the device may emit green light with CIE 1931 (x, y)=(0.100, 0.810), which as can be seen from FIG. 8b, is more saturated than the green primary colour for the Rec. 2020 standard, which has CIE 1931 (x, y)=(0.170, 0.797).

As described herein, the colour saturation of blue light emission from exemplary perovskite emissive layers may be slightly less than that required to render the blue primary colour of the Rec. 2020 standard. For example, as shown in Table 1, a perovskite light emitting device comprising a perovskite emissive layer may emit blue light with CIE 1931 (x, y)=(0.166, 0.079), which as can be seen from FIG. 8b, is less saturated than the blue primary color for the Rec. 2020 standard, which has CIE 1931 (x, y)=(0.131, 0.046). However, under some circumstances, including a perovskite light emitting device comprising a perovskite emissive layer that emits blue light may provide the device with one or more advantages, such as improved efficiency, higher brightness, improved operational lifetime, lower voltage and/or reduced cost, and may therefore be preferred.

The foregoing description demonstrates the potential for perovskite light emitting materials and devices to enhance the performance of displays. However, until now, perovskite emissive layers in perovskite light emitting devices such as those in Adjokatse et al., Hirose et al., Kumar et al. and Wang et al. have been assembled using solution-process laboratory techniques, such as spin-coating, which are not compatible with manufacturing processes for displays. Here we disclose a method for the assembly of perovskite emissive layers for application in perovskite light emitting devices, such as a displays, that is readily compatible with manufacturing processes for displays.

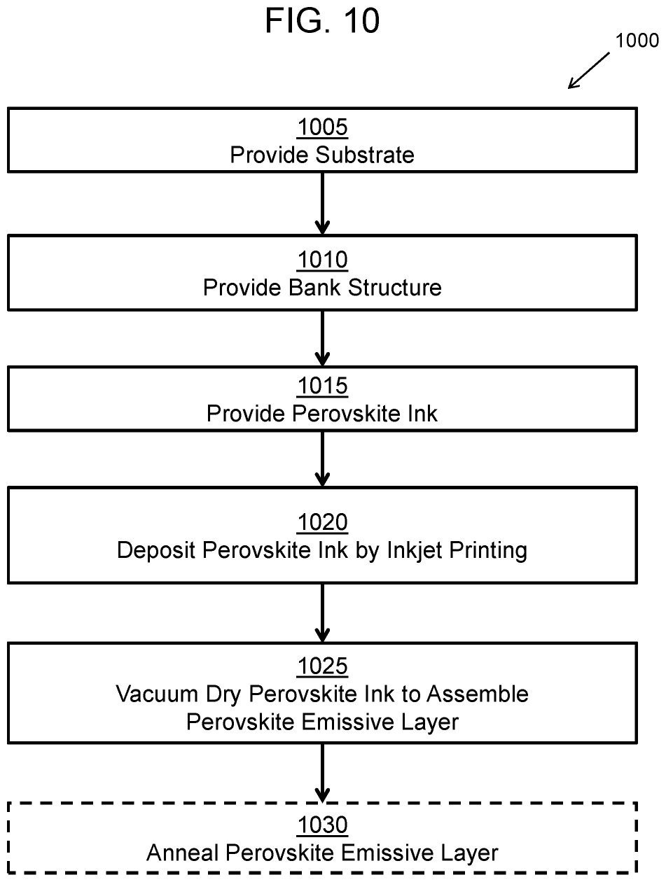

FIG. 10 depicts a method 1000 for assembling a perovskite emissive layer. The method 1000 comprises: step 1005 of providing a substrate, which is labelled “Provide Substrate”; step 1010 of providing a bank structure disposed over the substrate, wherein the bank structure is patterned so as to define at least one sub-pixel on the substrate, which is labelled “Provide Bank Structure”; step 1015 of providing a perovskite ink, wherein the perovskite ink comprises at least one solvent and at least one perovskite light emitting material mixed in the at least one solvent, which is labelled “Provide Perovskite Ink”; step 1020 of depositing the perovskite ink into the at least one sub-pixel over the substrate using a method of inkjet printing, which is labelled “Deposit Perovskite Ink by Inkjet Printing”; and step 1025 of vacuum drying the perovskite ink inside a vacuum drying chamber to assemble a perovskite emissive layer in the at least one sub-pixel, which is labelled “Vacuum Dry Perovskite Ink to Assemble Perovskite Emissive Layer”. Optionally, the method 1000 comprises an additional step 1030 at the end of the process flow of annealing the perovskite emissive layer, which is labelled as “Anneal Perovskite Emissive Layer”.

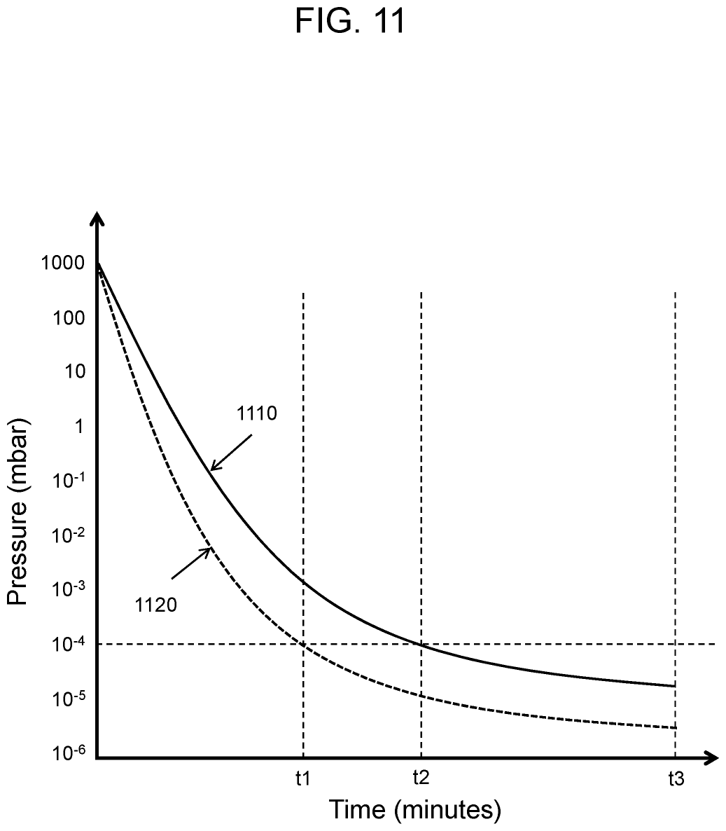

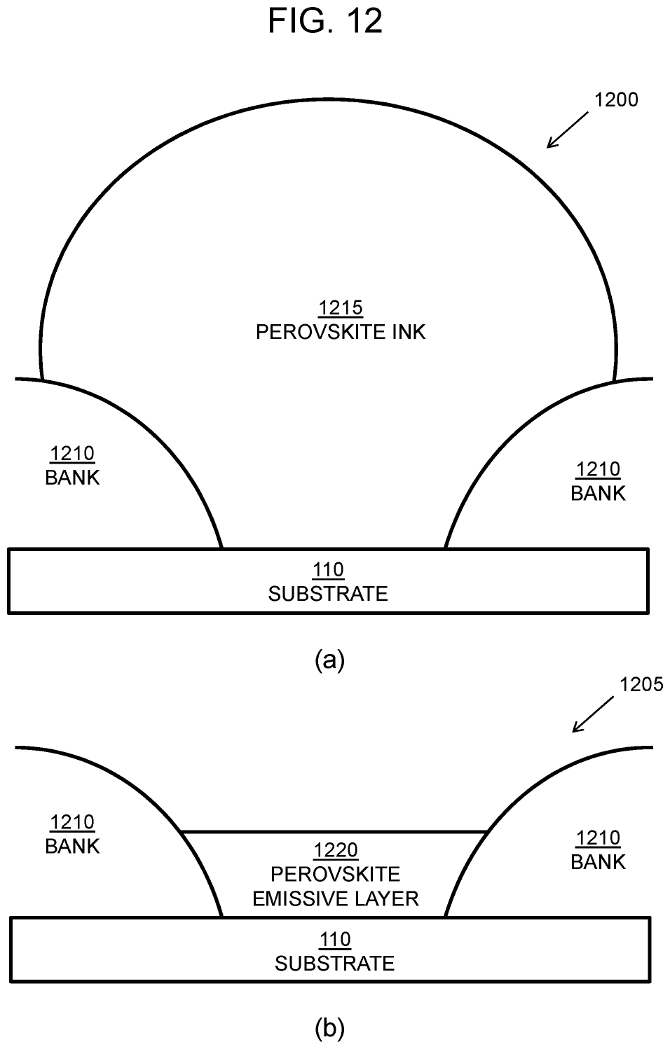

Method 1000 may be understood with reference to FIG. 11, which depicts exemplary vacuum drying curves 1110 and 1120 that may be applied during step 1025, as well as with reference to FIG. 12, which depicts the assembly of a perovskite emissive layer 1220 from a perovskite ink 1215.

Method 1000 comprises a step 1005 of providing a substrate 110. The substrate 110 may be rigid or flexible. The substrate 110 may be flat or curved. The substrate 110 may be transparent, translucent or opaque. Preferred substrate 110 materials are glass, plastic and metal foil. Method 1000 further comprises a step 1010 of providing a bank structure 1210 disposed over the substrate 110, wherein the bank structure 1210 is patterned so as to define at least one sub-pixel on the substrate 110. The bank structure 1210 defines the area into which perovskite ink 1215 may be inkjet printed and contained. For a display, the defined area may correspond to a sub-pixel of the display. Method 1000 further comprises a step 1015 of providing a perovskite ink 1215, wherein the perovskite ink 1215 comprises at least one solvent and at least one perovskite light emitting material mixed in the at least one solvent. The at least one solvent is needed to solubilize the at least one perovskite light emitting material to form a perovskite ink 1215 that can be inkjet printed.

Method 1000 further comprises a step 1020 of depositing the perovskite ink 1215 into the at least one sub-pixel over the substrate 110 using a method of inkjet printing. Inkjet printing has several advantages over other deposition techniques. Inkjet printing is readily compatible with manufacturing processes for displays. Ink droplets may be printed uniformly with high accuracy and at high speed across large area substrates. Ink droplets may be printed on demand with no more than the necessary ink volume for each layer deposited into each sub-pixel, resulting in substantially higher material utilization than for vacuum deposition processes. Inkjet printing allows for inks for red, green and blue emissive layers to be deposited within different sub-pixels of a display, without the need for expensive fine metal masks that would be required for patterning red, green and blue emissive layers within different sub-pixels of a display using vapour deposition processes. The inkjet printing process may be performed in an atmosphere of air or nitrogen, avoiding the need for expensive vacuum chambers, as required to deposit layers using vacuum deposition processes.

Arrangement 1200 in FIG. 12a depicts a perovskite ink 1215 that has been deposited into the at least one sub-pixel over a substrate 110 using a method of inkjet printing. The sub-pixel is defined by a bank structure 1210. In one embodiment, the step of depositing the perovskite ink 1215 into the at least one sub-pixel over the substrate 110 by inkjet printing is performed in an atmosphere of air. In one embodiment, the step of depositing the perovskite ink 1215 into the at least one sub-pixel over the substrate 110 by inkjet printing is performed in an atmosphere of nitrogen.

Method 1000 further comprises a step 1025 of vacuum drying the perovskite ink inside a vacuum drying chamber to assemble a perovskite emissive layer 1220 in the at least one sub-pixel. The process of vacuum drying can be understood with reference to FIG. 12. Arrangement 1200 in FIG. 12a depicts the status of method 1000 after step 1020, but before step 1025. That is to say, arrangement 1200 depicts the status before the step of vacuum drying the perovskite ink 1215. During step 1025, the arrangement 1200 is transferred to a vacuum drying chamber. Within the vacuum drying chamber, ambient pressure is reduced to extract one or more solvents from the perovskite ink 1215. This causes the perovskite ink 1215 to contract and solidify to assemble a perovskite emissive layer 1220. Arrangement 1205 in FIG. 12b depicts the status of method 1000 after step 1025. That is to say, arrangement 1205 depicts the status after the step of vacuum drying the perovskite ink 1215. After vacuum drying, one or more solvents have been extracted from perovskite ink 1215, and a perovskite emissive layer 1220 has been assembled.

Vacuum drying has several advantages over other layer assembly techniques. For example, the rate at which one or more solvents are extracted from the perovskite ink 1215 may be controlled by varying the rate at which pressure is reduced in a vacuum drying chamber. This enables both the profile and morphology of the assembled perovskite emissive layer 1220 to be controlled by varying the rate of vacuum drying of the perovskite ink 1215. Using an external factor, such as ambient pressure, to control the morphology and profile of the perovskite emissive layer 1220 is advantageous compared to self-assembly techniques, such as those disclosed in Wang et al. because the perovskite emissive layer 1220 properties may be controlled more precisely and with greater reproducibility.

Vacuum drying enables perovskite emissive layers 1220 to be assembled rapidly across large area substrates 110, as required in the manufacturing process for displays, where takt times are typically of order 90-120 seconds. This cannot be achieved by alternative drying processes such as annealing a perovskite ink 1215 to assemble a perovskite emissive layer 1220, which is the method that has been used in all previous work on light emitting perovskite devices. As disclosed herein, an optional additional step 1030 of annealing the perovskite emissive layer 1220 after it has been assembled by a step 1025 of vacuum drying is advantageous. Such an optional additional annealing step 1030 would not assemble the perovskite emissive layer 1220 from the perovskite ink 1215 because the perovskite emissive layer 1220 would already have been assembled during the vacuum drying step 1025. Such an optional additional annealing step 1030 would instead remove residual solvent from the assembled perovskite emissive layer 1220 and optimize the morphology of the perovskite emissive layer 1220.

The process of vacuum drying may be further understood with reference to FIG. 11, which depicts two exemplary vacuum drying curves 1110 and 1120, which may be applied during step 1025.

In one embodiment, during the step 1025 of vacuum drying the perovskite ink 1215, the pressure inside the vacuum drying chamber may be reduced to less than or equal to 0.0001 mbar. By reducing the pressure to less than or equal to 0.0001 mbar, one or more solvents may be extracted from the perovskite ink 1215 to assemble a perovskite emissive layer 1220. Furthermore, by reducing the pressure to less than or equal to 0.0001 mbar, very little residual solvent may remain in the perovskite emissive layer 1220 after step 1025.

In one embodiment, during the step 1025 of vacuum drying the perovskite ink 1215, the pressure inside the vacuum drying chamber may be reduced to less than or equal to 0.0001 mbar in less than or equal to 60 seconds. For example, by applying vacuum drying curve 1110 in FIG. 11, the pressure reaches 0.0001 mbar in time t2, where t2 may be less than or equal to 60 seconds. In one embodiment, during the step 1025 of vacuum drying the perovskite ink 1215, the pressure inside the vacuum drying chamber may be reduced to less than or equal to 0.0001 mbar in less than or equal to 30 seconds. For example, by applying vacuum drying curve 1120 in FIG. 11, the pressure reaches 0.0001 mbar in time t1, where t1 may be less than or equal to 30 seconds. In one embodiment, the duration of the step 1025 of vacuum drying the perovskite ink 1215 may be less than or equal to 120 seconds. For example, by applying vacuum drying curves 1110 or 1120 in FIG. 11, the vacuum drying process may be completed at time t3, where t3 may be less than or equal to 120 seconds. Such vacuum drying process times are compatible with in-line manufacturing processes for displays, where takt time is typically of order 90-120 seconds.

Note that in the foregoing, the start of the vacuum drying process is defined as the point in time at which the ambient pressure inside the vacuum drying chamber starts to be reduced from a pressure of approximately 1000 mbar, and the end of the vacuum drying process is defined as the time at which the ambient pressure returns to a pressure of approximately 1000 mbar. The step 1025 of vacuum drying the perovskite ink 1215 may include additional time for processes such as transfer and alignment of the substrate, but such additional time is not included in the foregoing discussion of vacuum drying process times.

Preferably, during the step 1025 of vacuum drying the perovskite ink 1215 to assemble the perovskite emissive layer 1220, the ambient temperature inside the vacuum drying chamber is 50° C. or less, optionally 30° C. or less. This low temperature ensures that the perovskite ink 1215 does not dry prematurely to assemble a non-uniform perovskite emissive layer 1220 during transfer of the substrate 110 into the vacuum drying chamber. For example, if the ambient temperature inside the vacuum drying chamber were higher than approximately 50° C., the perovskite ink 1215 disposed over the area of the substrate 110 that enters the vacuum chamber first would begin to dry before the perovskite ink 1215 disposed over the area of the substrate 110 that enters the vacuum chamber last. This would result in an imbalance of vapour pressure and evaporation rate of the perovskite ink 1215 across the substrate 110 and the assembly of a non-uniform perovskite emissive layer 1220 with reduced optoelectronic performance.

The rate at which ambient pressure is reduced may be tuned according to the required perovskite emissive layer 1220 morphology and profile. The rate at which ambient pressure is reduced may also be tuned according to other additional factors that may influence the assembly and resultant morphology and profile of the perovskite emissive layer 1220. Such additional factors may include solid content of the perovskite ink, sub-pixel dimensions, volume of the perovskite ink drops, number of the perovskite ink drops and bank structure 1210 design. The ability to tune the rate at which ambient pressure is reduced during step 1025 in the disclosed method 1000 enables greater control over the assembly and resultant morphology and profile of a perovskite emissive layer 1220 compared to alternative self-assembly processes, such as those described in Wang et al.

The assembly and resultant thickness, morphology or profile of the assembled perovskite emissive layer 1220 may be further influenced by the solid content of the perovskite ink 1215. In one embodiment, the perovskite ink 1215 may comprise at least one perovskite light emitting material mixed in at least one solvent at a concentration by weight in the range of 0.01 wt. % to 10 wt. %. In one embodiment, the perovskite ink 1215 may comprise at least one perovskite light emitting material mixed in at least one solvent at a concentration by weight of in the range of 0.1 wt. % to 5 wt. %.

Such a range of concentration by weight of perovskite light emitting material in the perovskite ink 1215 may enable the thickness of the perovskite emissive layer 1220 to be controlled. For example, by increasing the concentration by weight of the perovskite light emitting material, the thickness of the perovskite emissive layer 1220 may be increased. In one embodiment, the thickness of the perovskite emissive layer 1220 may be in the range of 15 nm to 150 nm. Such a thickness range may maximize the proportion of recombination of electrons and holes within the perovskite emissive layer 1220, thereby maximizing the efficiency of light emission from the perovskite emissive layer 1220.

Such a range of concentration by weight of perovskite light emitting material in the perovskite ink 1215 may further enable the morphology and profile of the perovskite emissive layer 1220 to be controlled. For example, a perovskite ink 1215 with higher weight concentration of perovskite light emitting material may be of higher viscosity than a perovskite ink 1215 with lower weight concentration of perovskite light emitting material. The change in viscosity may affect how the perovskite ink 1215 contracts and solidifies to form a perovskite emissive layer 1220 during vacuum drying. With different perovskite ink 1215 viscosity, the movement of perovskite light emitting material within the perovskite ink 1215 may be different during the vacuum drying process, which may result in a different morphology of perovskite light emitting material in the resultant perovskite emissive layer 1220 after vacuum drying, as well as a different profile of the resultant perovskite emissive layer 1220.

Note that as described herein, the perovskite emissive layer 1220 thickness is defined as the thickness of the perovskite emissive layer 1220 at the centre of the at least one sub-pixel. It is not defined as the thickness of the perovskite emissive layer 1220 in regions of the at least one sub-pixel over or adjacent to the bank structure 1210. For a well-controlled application of method 1000, the resulting perovskite emissive layer 1220 may be of uniform thickness across the at least one sub-pixel, with less than approximately 10%, and optionally less than approximately 5% thickness variation across the at least one sub-pixel. However, in some instances, application of method 1000 may result in substantial thickness variation of the perovskite emissive layer 1220 across the at least one sub-pixel. In all instances, the thickness of the perovskite emissive layer 1220 is defined at the centre of the at least one sub-pixel.

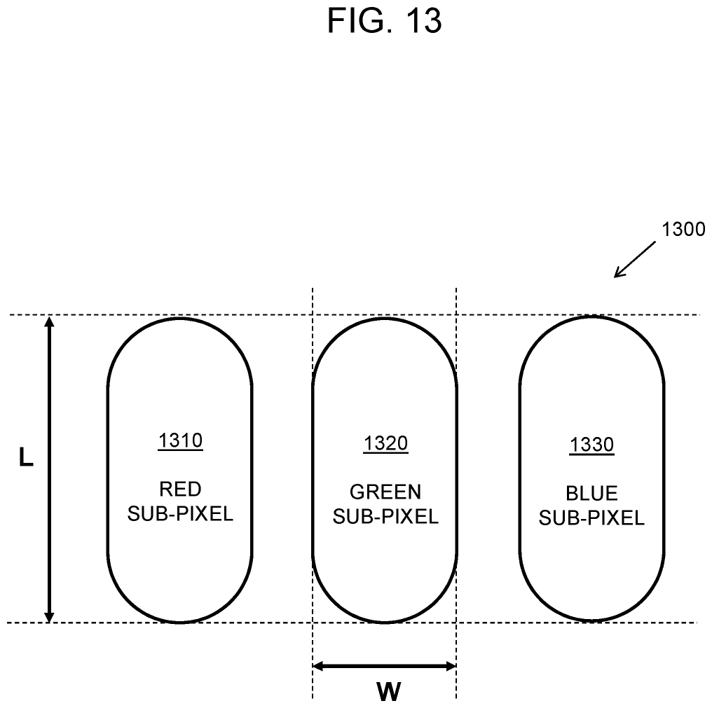

The assembly and resultant morphology or profile of the assembled perovskite emissive layer 1220 may be further influenced by the dimensions of the at least one sub-pixel into which the perovskite ink 1215 is inkjet printed. The dimensions of the at least one sub-pixel may be defined by the bank structure 1210. FIG. 13 depicts exemplary designs of sub-pixels. Included in FIG. 13 is an arrangement 1300 of three adjacent sub-pixels, each of length L and width W. The first sub-pixel 1310 may comprise a red sub-pixel, wherein such a red sub-pixel may comprise a red perovskite light emitting device comprising a red perovskite emissive layer 1220. The second sub-pixel 1320 may comprise a green sub-pixel, wherein such a green sub-pixel may comprise a green perovskite light emitting device comprising a green perovskite emissive layer 1220. The third sub-pixel 1330 may comprise a blue sub-pixel, wherein such a blue sub-pixel may comprise a blue perovskite light emitting device comprising a blue perovskite emissive layer 1220. A typical pixel arrangement of a commercial display may comprise a sub-pixel arrangement such as 1300.

In one embodiment, the at least one sub-pixel into which the perovskite ink 1215 is inkjet printed may be of length in the range of 100 μm to 250 μm, and of width in the range of 40 μm to 80 μm. Such ranges of sub-pixel lengths and widths correspond to the dimensions required for television displays of size approximately 55-inch to 77-inch with 4K2K pixel resolution, or more formally 3840×2160 pixel resolution, which is also referred to as ultra-high definition (UHD) resolution. In one embodiment, the at least one sub-pixel into which the perovskite ink 1215 is inkjet printed may be of length in the range of 50 μm to 150 μm, and of width in the range of 20 μm to 40 μm. Such ranges of sub-pixel lengths and widths correspond to the dimensions required for television displays of size approximately 55-inch to 77-inch with 8K pixel resolution, or more formally 7680×4320 pixel resolution, which is also referred to as 8K ultra high definition (8K UHD). In one embodiment, the at least one sub-pixel into which the perovskite ink 1215 is inkjet printed may be of length in the range of 10 μm to 50 μm, and of width in the range of 5 μm to 20 μm. Such ranges of sub-pixel lengths and widths correspond to the dimensions required for smartphone displays of resolution in the approximate range of 400 to 600 pixels per inch (ppi).

The assembly and resultant thickness, morphology or profile of the assembled perovskite emissive layer 1220 may be further influenced by the perovskite ink drop volume during the step of depositing the perovskite ink 1215. For example, the profile of the perovskite emissive layer 1220 may be tuned by using a larger number of drops of lower volume, or a lower number of drops of larger volume. In one embodiment, the profile of the assembled perovskite emissive layer 1220 may be controlled by varying the perovskite ink drop volume during the step of depositing the perovskite ink 1215.

For larger sub-pixels, perovskite ink drops with a larger volume may be used during the step of depositing the perovskite ink 1215. In one embodiment, the perovskite ink drop volume may be in the range of 5 pico-liters to 15 pico-liters. Such a range of perovskite ink drop volumes may be suitable for inkjet printing perovskite ink 1215 into sub-pixels of length in the range of 100 μm to 250 μm, and of width in the range of 40 μm to 80 μm, as required for television displays of size approximately 55-inch to 77-inch with 4K2K pixel resolution. Such a range of perovskite ink drop volumes may also be suitable for inkjet printing perovskite ink 1215 into sub-pixels of length in the range of 50 μm to 150 μm, and of width in the range of 20 μm to 40 μm, as required for television displays of size approximately 55-inch to 77-inch with 8K pixel resolution.

For smaller sub-pixels, perovskite ink drops with a smaller volume may be used during the step of depositing the perovskite ink 1215. In one embodiment, the perovskite ink drop volume during may be in the range of 0.5 pico-liters to 2 pico-liters. Such a range of perovskite ink drop volumes may be suitable for inkjet printing perovskite ink 1215 into sub-pixels of length in the range of 10 μm to 50 μm, and of width in the range of 5 μm to 20 μm, as required for smartphone displays of resolution in the approximate range of 400 to 600 pixels per inch (ppi).

The assembly and resultant thickness, morphology or profile of the assembled perovskite emissive layer 1220 may be further influenced by the number of perovskite ink drops during the step of depositing the perovskite ink 1215. In one embodiment, the profile of the assembled perovskite emissive layer 1220 may be controlled by varying the number of perovskite ink drops during the step of depositing the perovskite ink 1215. For example, the profile of the perovskite emissive layer 1220 may be tuned by using a larger number of drops of lower volume or a lower number of drops of larger volume. In one embodiment, the total number of perovskite ink drops may in the range of 4 perovskite ink drops to 20 perovskite ink drops. A larger number of perovskite ink drops of lower volume may allow for the perovskite ink 1215 to be spread more evenly across the sub-pixel, potentially resulting in a more uniform perovskite emissive layer 1220 after vacuum drying of the perovskite ink 1215. Conversely, a lower number of perovskite ink drops of larger volume may allow for the perovskite ink 1215 to be inkjet printed more rapidly, enabling a reduced takt time during the manufacturing process.

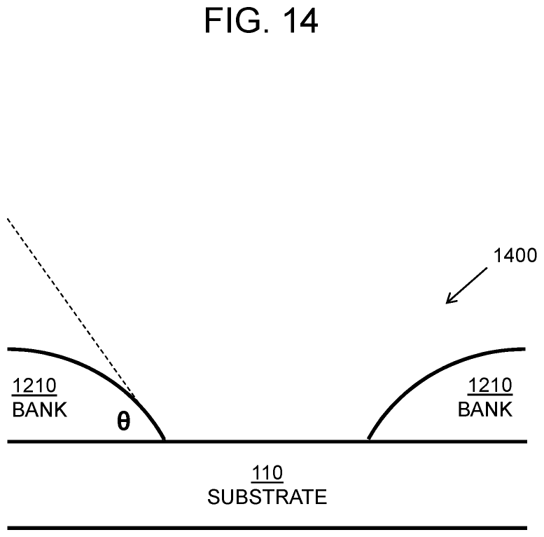

The assembly and resultant thickness, morphology or profile of the assembled perovskite emissive layer 1220 may be further influenced by the bank structure 1210 used to define the at least one sub-pixel. FIG. 14 depicts arrangement 1400, which depicts a cross-section of a bank structure 1210 disposed over a substrate 110. The bank structure 1210 is disposed over the substrate 110 such that the bank structure 1210 is inclined at an angle θ at the edge of the at least one sub-pixel. In one embodiment, the profile of the assembled perovskite emissive layer 1220 may be controlled by varying the angle of the bank structure 1210 at the edge of the at least one sub-pixel. For example, where the angle θ is lower, the perovskite ink 1215 may spread further over the bank structure 1210, which may influence the layer profile when the perovskite ink 1215 is vacuum dried to assemble a perovskite emissive layer 1220. In one embodiment, the bank structure 1210 may be provided at an angle θ in the range of 30° to 60° at the edge of the at least one sub-pixel. Such a range of angles θ may effectively contain the perovskite ink 1215 within the sub-pixel, while also allowing the perovskite ink 1215 to assemble a uniform perovskite emissive layer 1220 during vacuum drying.

In one embodiment, the profile of the assembled perovskite emissive layer 1220 may be controlled by varying the surface energy of the bank structure 1210. For example, if the surface energy of the bank structure 1210 is substantially higher than the surface energy of the perovskite ink 1215, then the perovskite ink 1215 may be attracted to and spread over the surface of the bank structure 1210. However, if the surface energy of the bank structure 1210 is not substantially higher than the surface energy of the perovskite ink 1215, then the perovskite ink 1215 may be repelled from and not spread over the bank structure 1210. In one embodiment, the surface energy of the bank structure 1210 may be controlled such that the lower proportion of the bank structure 1210, nearest the substrate 110, has substantially higher surface energy than the perovskite ink 1215, while the upper proportion of the bank structure 1210, furthest away from the substrate 110, does not have substantially higher surface energy than the perovskite ink 1215. This may enable the perovskite ink 1215 to spread evenly across the sub-pixel and remain in contact with the lower proportion of the bank structure 1210 without any de-wetting, but prevent the perovskite ink 1215 from spreading over the upper proportion of the bank structure 1210 into one or more adjacent sub-pixels. The perovskite ink 1215 may then assemble a uniform perovskite emissive layer 1220 after vacuum drying.

Referring once more to FIG. 10, which depicts the method 1000 for assembling a perovskite emissive layer 1220 from a perovskite ink 1215. In one embodiment, after step 1025, the method 1000 comprises an additional step 1030 of annealing the perovskite emissive layer 1220, which is labelled in FIG. 10 as “Anneal Perovskite Emissive Layer”. The optional additional step 1030 is marked by a box outlined with a dashed line in FIG. 10. The dashed line represents that the additional step 1030 is an optional step in method 1000. In contrast, the other boxes 1005, 1010, 1015, 1020 and 1025 are outlined with a solid line in FIG. 10. The solid line represents that these are not optional steps in method 1000.

By annealing the perovskite emissive layer 1220, any residual solvent may be removed from the perovskite emissive layer 1220. Furthermore, by annealing the perovskite emissive layer 1220, the thickness, morphology or profile of the perovskite emissive layer 1220 may be defined by any movement of the perovskite emissive layer 1220 during extraction of any residual solvent during the annealing process. In one embodiment, the perovskite emissive layer 1220 may be a cross-linked layer, and after the step 1030 of annealing the perovskite emissive layer, the perovskite emissive layer 1220 may be cross-linked.

In one embodiment, during the step 1030 of annealing the perovskite emissive layer 1220, the annealing temperature may be in the range of 80° C. to 200° C. In one embodiment, during the step 1030 of annealing the perovskite emissive layer 1220, the annealing temperature may be in the range of 80° C. to 160° C. Such a range annealing of temperatures may effectively enable any residual solvent to be removed from the perovskite emissive layer 1220. In one embodiment, the step 1030 of annealing the perovskite emissive layer 1220 may be performed in a different chamber to the vacuum drying chamber. In one embodiment, the step 1030 of annealing the perovskite emissive layer 1220 may be performed in the same chamber as the vacuum drying chamber. In one embodiment, the step 1030 of annealing the perovskite emissive layer 1220 may be performed during the step 1025 of vacuum drying the perovskite ink 1215.

Preferably, the step 1030 of annealing the perovskite emissive layer 1220 is performed in a different step to the step 1025 of vacuum drying the perovskite ink 1215. Preferably, the step 1030 of annealing the perovskite emissive layer 1220 is performed in a different chamber to the step 1025 of vacuum drying the perovskite ink 1215. Preferably, the step 1030 of annealing the perovskite emissive layer 1220 is performed in a different step and in a different chamber to the step 1025 of vacuum drying the perovskite ink 1215. This enables the vacuum drying step 1025 to be performed at an ambient temperature of 50° C. or less, optionally 30° C. or less, which as described herein, ensures the perovskite ink 1215 does not dry prematurely to assemble a non-uniform perovskite emissive layer 1220 during transfer of the substrate 110 into the vacuum drying chamber. Furthermore, process times for the step 1025 of vacuum drying the perovskite ink 1215 and the step 1030 of annealing the perovskite emissive layer 1220 may be individually optimized. For example, a typical optimized vacuum drying step 1025 may be expected to be 90-120 seconds, whereas a typical optimized annealing step 1020 may be expected to be in the range of 10 minutes to 30 minutes, such that multiple substrates are required to be loaded into a single annealing chamber to ensure a steady process flow for manufacturing displays. Separating the step 1025 of vacuum drying and the step 1030 of annealing thereby enables an optimized manufacturing process flow with a takt time of 90-120 seconds. This is a substantial improvement over the related art disclosed in patent applications WO 2017/080325 A1 and US 2018/0327622 A1, where vacuum drying and annealing are performed in a single step of high temperature vacuum drying, which results in the assembly of non-uniform perovskite emissive layers 1220 with reduced optoelectronic performance and a non-optimized manufacturing process flow with higher cost.

In one embodiment, the step 1030 of annealing the perovskite emissive layer 1220 may be performed in an atmosphere of nitrogen. Such a nitrogen atmosphere may be preferred for the annealing process because one or more materials within the perovskite emissive layer 1220 may be susceptible to oxidation and degradation when annealed in an atmosphere of air.

The present invention relates to a method 1000 of assembling a perovskite emissive layer 1220 from a perovskite ink 1215. The present invention further relates to a perovskite emissive layer 1220 assembled using the disclosed method. Such a perovskite emissive layer 1220 may be implemented in a perovskite light emitting device comprising a perovskite emissive layer 1220. The present invention further relates to perovskite light emitting devices comprising a perovskite emissive layer 1220 assembled using the disclosed method.

In one embodiment, the perovskite light emitting device may be incorporated into a sub-pixel of a display. Optionally, the display may be incorporated into a wide range of consumer products. Optionally, the display may be used in televisions, computer monitors, tablets, laptop computers, smart phones, cell phones, digital cameras, video recorders, smartwatches, fitness trackers, personal digital assistants, vehicle displays and other electronic devices. Optionally, the display may be used for micro-displays or heads-up displays. Optionally, the display may be used in light sources for interior or exterior illumination and/or signaling, in smart packaging or in billboards.

A person skilled in the art will understand that only a few examples of use are described, but that they are in no way limiting.

Modifications to embodiments of the invention described in the foregoing are possible without departing from the scope of the invention as defined by the accompanying claims. Expressions such as “including”, “comprising”, “incorporating”, “consisting of”, “have”, “is” used to describe and claim the present invention are intended to be construed in a non-exclusive manner, namely allowing for items, components or elements not explicitly described also to be present. Reference to the singular is also to be construed to relate to the plural. Any numerals included within parentheses in the accompanying claims are intended to assist understanding of the claims and should not be construed in any way to limit subject matter claimed by these claims.

### REFERENCES

Adjokatse et al., Broadly tunable metal halide perovskites for solid-state light-emission applications, Materials Today, Volume 20, Issue 8, Pages 413-424 (2017).
Hirose et al., High-efficiency Perovskite QLED Achieving BT.2020 Green Chromaticity, SID Symposium Digest of Technical Papers 2017, Volume 48, Pages 284-287 (2017).
Kumar et al., Efficient Blue Electroluminescence Using Quantum-Confined Two-Dimensional Perovskites, ACS Nano, Volume 10, Pages 9720-9729 (2016).
Soneira et al., iPhone X OLED Display Technology Shoot-Out, DisplayMate Technologies Corporation, http://www.displaymate.com/iPhoneX ShootOut 1a.htm [accessed 10 September, 2018].
Wang et al., Perovskite light-emitting diodes based on solution-processed, self-organised multiple quantum wells, Nature Photonics, Volume 10, Pages 699-704 (2016).

1. A method of assembling a perovskite emissive layer, wherein the method comprises the following steps:
providing a substrate;
providing a bank structure disposed over the substrate, wherein the bank structure is patterned so as to define at least one sub-pixel on the substrate;
providing a perovskite ink, wherein the perovskite ink comprises at least one solvent and at least one perovskite light emitting material mixed in the at least one solvent;
depositing the perovskite ink into the at least one sub-pixel over the substrate using a method of inkjet printing; and
vacuum drying the perovskite ink inside a vacuum drying chamber to assemble a perovskite emissive layer in the at least one sub-pixel.

2. The method of claim 1, wherein the perovskite ink comprises organic metal halide light-emitting perovskite material.

3. The method of claim 1, wherein the perovskite ink comprises inorganic metal halide light-emitting perovskite material.

4. The method of any one of claims 1 to 3, wherein the profile of the assembled perovskite emissive layer may be controlled by varying the rate of vacuum drying of the perovskite ink.

5. The method of any one of claims 1 to 4, wherein the morphology of the assembled perovskite emissive layer may be controlled by varying the rate of vacuum drying of the perovskite ink.

6. The method of any one of claims 1 to 5, wherein during the step of vacuum drying the perovskite ink, the pressure inside the vacuum drying chamber is reduced to less than or equal to 0.0001 mbar.

7. The method of any one of claims 1 to 5, wherein during the step of vacuum drying the perovskite ink, the pressure inside the vacuum drying chamber is reduced to less than or equal to 0.0001 mbar in less than or equal to 60 seconds.

8. The method of any one of claims 1 to 5, wherein during the step of vacuum drying the perovskite ink, the pressure inside the vacuum drying chamber is reduced to less than or equal 0.0001 mbar in less than or equal to 30 seconds.

9. The method of any one of the preceding claims, wherein the duration of the step of vacuum drying the perovskite ink is less than or equal to 120 seconds.

10. The method of any one of the preceding claims, wherein during the step of vacuum drying the perovskite ink, the ambient temperature inside the vacuum drying chamber is 50° C. or less, optionally 30° C. or less.

11. The method of any one of the preceding claims, wherein the perovskite ink comprises at least one perovskite light emitting material mixed in the at least one solvent at a concentration by weight in the range of 0.01 wt. % to 10 wt. %.

12. The method of any one of claims 1 to 10, wherein the perovskite ink comprises at least one perovskite light emitting material mixed in the at least one solvent at a concentration by weight in the range of 0.1 wt. % to 5 wt. %.

13. The method of any one of the preceding claims, wherein the thickness of the assembled perovskite emissive layer is in the range of 15 nm to 150 nm.

14. The method of any one of the preceding claims, wherein the profile of the assembled perovskite emissive layer may be controlled by varying dimensions of the at least one sub-pixel.

15. The method of any one of the preceding claims, wherein the profile of the assembled perovskite emissive layer may be controlled by varying the perovskite ink drop volume during the step of depositing the perovskite ink.

16. The method of any one of the preceding claims, wherein the length of the at least one sub-pixel is in the range of 100 μm to 250 μm, and the width of the at least one sub-pixel is in the range of 40 μm to 80 μm.

17. The method of any one of claims 1 to 15, wherein the length of the at least one sub-pixel is in the range of 50 μm to 150 μm, and the width of the at least one sub-pixel is in the range of 20 μm to 40 μm.

18. The method of any one of claims 1 to 15, wherein the length of the at least one sub-pixel is in the range of 10 μm to 50 μm, and the width of the at least one sub-pixel is in the range of 5 μm to 20 μm.

19. The method of any one of the preceding claims, wherein the perovskite ink drop volume during the step of depositing the perovskite ink is in the range of 5 pico-liters to 15 pico-liters.

20. The method of any one of claims 1 to 18, wherein the perovskite ink drop volume during the step of depositing the perovskite ink is in the range of 0.5 pico-liters to 2 pico-liters.

21. The method of any one of the preceding claims, wherein the profile of the assembled perovskite emissive layer may be controlled by varying the number of perovskite ink drops during the step of depositing the perovskite ink.

22. The method of any one of the preceding claims, wherein the total number of perovskite ink drops deposited during the step of depositing the perovskite may be in the range of 4 perovskite ink drops to 20 perovskite ink drops.

23. The method of any one of the preceding claims, wherein the profile of the assembled perovskite emissive layer may be controlled by varying the angle of the bank structure at the edge of the at least one sub-pixel.

24. The method of any one of the preceding claims, wherein the bank structure is provided at an angle in the range of 30° to 60° at the edge of the at least one sub-pixel.

25. The method of any one of the preceding claims, wherein the profile of the perovskite emissive layer may be controlled by varying the surface energy of the bank structure.

26. The method of any one of the preceding claims, wherein the step of depositing the perovskite ink is performed in an atmosphere of air.

27. The method of any one of claims 1 to 25, wherein the step of depositing the perovskite ink is performed in an atmosphere of nitrogen.

28. The method of any one of the preceding claims, wherein after the step of vacuum drying the perovskite ink inside a vacuum drying chamber to assemble a perovskite emissive layer in the at least one sub-pixel, the method further comprises a step of annealing the perovskite emissive layer.

29. The method of claim 28, wherein during the step of annealing the perovskite emissive layer, the annealing temperature is in the range of 80° C. to 200° C.

30. The method of claim 28 or claim 29, wherein the step of annealing the perovskite emissive layer is performed in an atmosphere of nitrogen.

31. The method of any one of claims 28 to 30, wherein the step of annealing the perovskite emissive layer is performed in a different chamber to the step of vacuum drying the perovskite ink inside a vacuum drying chamber to assemble a perovskite emissive layer in the at least one sub-pixel.

32. A perovskite emissive layer assembled by the method of any one of claims 1 to 31.

33. A perovskite light emitting device comprising the perovskite emissive layer of claim 32.
